(19) United States
(12) Patent Application Publication
(10) Pub. No.: US 2025/0160111 A1
(43) Pub. Date: May 15, 2025

(54) LIGHT EMITTING DEVICE AND DISPLAY APPARATUS

(71) Applicants: Beijing BOE Technology Development Co., Ltd., Beijing (CN); BOE Technology Group Co., Ltd., Beijing (CN)

(72) Inventors: Yichi Zhang, Beijing (CN); Zhigao Lu, Beijing (CN); Jian Xu, Beijing (CN)

(73) Assignees: Beijing BOE Technology Development Co., Ltd., Beijing (CN); BOE Technology Group Co., Ltd., Beijing (CN)

(21) Appl. No.: 18/729,123

(22) PCT Filed: Nov. 13, 2023
(86) PCT No.: PCT/CN2023/131266

§ 371 Date: Jul. 15, 2024

(51) Int. Cl. H10K 50/125

(52) U.S. Cl. CPC H10K 50/125

(57) ABSTRACT

A light emitting device is provided. The light emitting device includes a first electrode; a second electrode; and a first functional layer, a first quantum dots layer of a first color, a first auxiliary quantum dots layer, and a second functional layer between the first electrode and the second electrode. One or more first quantum dots of the first quantum dots layer of the first color is at least partially embedded in the first functional layer. A first functional material in the first functional layer is at least partially cross-linked.

### TECHNICAL FIELD

The present invention relates to display technology, more particularly, to a light emitting device and a display apparatus.

### BACKGROUND

Quantum dots material has excellent optical and electrical properties, including a narrow emission peak (with a half-peak width of approximately 30 nm), a tunable spectrum (ranging from visible light to infrared light), high photochemical stability, and a low starting voltage. Wavelengths of light emitted from quantum dots materials are tunable at least in part based on the particle sizes of the quantum dots. Due to these excellent properties, quantum dots have become a focus of research and development in the fields of display technology.

### SUMMARY

In one aspect, the present disclosure provides a light emitting device, comprising a first electrode; a second electrode; and a first functional layer, a first quantum dots layer of a first color, a first auxiliary quantum dots layer, and a second functional layer between the first electrode and the second electrode; wherein one or more first quantum dots of the first quantum dots layer of the first color is at least partially embedded in the first functional layer; and a first functional material in the first functional layer is at least partially cross-linked.

Optionally, the first auxiliary quantum dots layer is in contact with the first functional layer and in contact with the second functional layer; and the first auxiliary quantum dots layer is in contact with the first quantum dots layer of the first color.

Optionally, with respect to the first quantum dots layer of the first color and the first functional layer, a majority of a first quantum dots material is distributed in the first quantum dots layer of the first color, and a minority of the first quantum dots material is distributed in the first functional layer; and with respect to the first quantum dots layer of the first color and the first functional layer, a majority of the first functional material is distributed in the first functional layer, and a minority of the first functional material is distributed in the first quantum dots layer of the first color.

Optionally, quantum dots materials in the first quantum dots layer of the first color comprise a first ligand; quantum dots materials in the first auxiliary quantum dots layer include a first auxiliary ligand and a second auxiliary ligand; ligands in the first quantum dots layer of the first color have a same polarity; and the first auxiliary ligand and the second auxiliary ligand have different polarities.

Optionally, the first ligand comprises a first binding group that binds to an inorganic portion of quantum dots materials in the first quantum dots layer of the first color and a first tail connected to the first binding group; the first auxiliary ligand includes a first auxiliary binding group that binds to an inorganic portion of quantum dots materials in the first auxiliary quantum dots layer and a first auxiliary tail connected to the first auxiliary binding group; and the second auxiliary ligand includes a second auxiliary binding group that binds to an inorganic portion of quantum dots materials in the first auxiliary quantum dots layer and a second auxiliary tail connected to the second auxiliary binding group; wherein the first tail has a first polarity; the first auxiliary tail has a second polarity; the second auxiliary tail has a third polarity; and a difference between the first polarity and the second polarity is smaller than a difference between the first polarity and the third polarity.

Optionally, the first auxiliary quantum dots layer is on a side of the first quantum dots layer away from the first functional layer.

Optionally, the second functional layer is on a side of the first auxiliary quantum dots layer away from the first quantum dots layer.

Optionally, the light emitting device further comprises a third functional layer on a side of the first functional layer away from the first quantum dots layer and the first auxiliary quantum dots layer; wherein the first functional layer is in contact with the third functional layer.

Optionally, the first quantum dots layer is on a side of the first auxiliary quantum dots layer and the second functional layer away from the first electrode; the first auxiliary quantum dots layer is on a side of the first quantum dots layer away from the first functional layer; the second functional layer is on a side of the first auxiliary quantum dots layer and the first quantum dots layer away from the first functional layer; and the first auxiliary quantum dots layer are in contact with the second functional layer.

Optionally, the first quantum dots layer has a non-uniform thickness; and a combination of the first quantum dots layer and the first auxiliary quantum dots layer has a non-uniform thickness.

Optionally, an orthographic projection of the first auxiliary quantum dots layer on a base substrate substantially covers an orthographic projection of the first quantum dots layer on the base substrate.

Optionally, an orthographic projection of the first auxiliary quantum dots layer on a base substrate is substantially non-overlapping with an orthographic projection of the first quantum dots layer on the base substrate.

Optionally, quantum dots materials in the first quantum dots layer of the first color comprise a first ligand; quantum dots materials in the first auxiliary quantum dots layer include a first auxiliary ligand; ligands in the first quantum dots layer of the first color have a same polarity; ligands in the first auxiliary quantum dots layer have a same polarity; and the first ligand and the first auxiliary ligand have different polarities.

Optionally, the first ligand comprises a first binding group that binds to an inorganic portion of quantum dots materials in the first quantum dots layer of the first color and a first tail connected to the first binding group; and the first auxiliary ligand includes a first auxiliary binding group that binds to an inorganic portion of quantum dots materials in the first auxiliary quantum dots layer and a first auxiliary tail connected to the first auxiliary binding group; wherein the first tail has a first polarity; the first auxiliary tail has a second polarity; and the first polarity is different from the second polarity.

Optionally, quantum dots materials in the first quantum dots layer of the first color and the first auxiliary quantum dots layer are quantum dots materials of the same color.

Optionally, the light emitting device comprises a first subpixel of the first color, a second subpixel of a second color, and a third subpixel of a third color; wherein the first subpixel of the first color comprises the first quantum dots layer and the first auxiliary quantum dots layer; the second subpixel of the second color comprises a second quantum dots layer and a second auxiliary quantum dots layer; the third subpixel of the third color comprises a third quantum dots layer and a third auxiliary quantum dots layer; quantum dots materials in the first quantum dots layer of the first color comprise a ligand having a fluorinated group; quantum dots materials in the second quantum dots layer of the second color comprise a ligand having a fluorinated group; quantum dots materials in the third quantum dots layer of the third color comprise a ligand having a fluorinated group; and a number of fluorine atoms in the ligands of the third quantum dots layer of the third color is greater than a number of fluorine atoms in the ligands of the first quantum dots layer of the first color, and is greater than a number of fluorine atoms in the ligands of the second quantum dots layer of the second color.

Optionally, the light emitting device comprises a first subpixel of the first color, a second subpixel of a second color, and a third subpixel of a third color; wherein the first subpixel of the first color comprises the first quantum dots layer and the first auxiliary quantum dots layer; the second subpixel of the second color comprises a second quantum dots layer and a second auxiliary quantum dots layer; the third subpixel of the third color comprises a third quantum dots layer and a third auxiliary quantum dots layer; quantum dots materials in the first auxiliary quantum dots layer comprise a ligand having a fluorinated group and/or a cyanide group; quantum dots materials in the second auxiliary quantum dots layer comprise a ligand having a fluorinated group and/or a cyanide group; quantum dots materials in the third auxiliary quantum dots layer comprise a ligand having a fluorinated group and/or a cyanide group; and a thickness of the third auxiliary quantum dots layer is greater than a thickness of the first auxiliary quantum dots layer, and is greater than a thickness of the second auxiliary quantum dots layer.

Optionally, the light emitting device comprises a first subpixel of the first color, a second subpixel of a second color, and a third subpixel of a third color; wherein the first subpixel of the first color comprises the first quantum dots layer and the first auxiliary quantum dots layer; the second subpixel of the second color comprises a second quantum dots layer and a second auxiliary quantum dots layer; the third subpixel of the third color comprises a third quantum dots layer and a third auxiliary quantum dots layer; quantum dots materials in the first auxiliary quantum dots layer comprise a ligand having a fluorinated group and/or a cyanide group; quantum dots materials in the second auxiliary quantum dots layer comprise a ligand having a fluorinated group and/or a cyanide group; quantum dots materials in the third auxiliary quantum dots layer comprise a ligand having a fluorinated group and/or a cyanide group; and a number of the fluorinated group and/or a cyanide group in the third auxiliary quantum dots layer is greater than a number of the fluorinated group and/or a cyanide group in the first auxiliary quantum dots layer, and is greater than a number of the fluorinated group and/or a cyanide group in the second auxiliary quantum dots layer.

Optionally, the light emitting device comprises a first subpixel of the first color, a second subpixel of a second color, and a third subpixel of a third color; wherein the first subpixel of the first color comprises the first quantum dots layer and the first auxiliary quantum dots layer; the second subpixel of the second color comprises a second quantum dots layer and a second auxiliary quantum dots layer; the third subpixel of the third color comprises a third quantum dots layer and a third auxiliary quantum dots layer; and a thickness of the first auxiliary quantum dots layer is greater than a thickness of the second auxiliary quantum dots layer; and the thickness of the second auxiliary quantum dots layer is greater than a thickness of the third auxiliary quantum dots layer.

In another aspect, the present disclosure provides a display apparatus, comprising a display panel; wherein the display panel comprises the light emitting device described herein, and one or more transistors configured to control light emission of the light emitting device.

### BRIEF DESCRIPTION OF THE FIGURES

The following drawings are merely examples for illustrative purposes according to various disclosed embodiments and are not intended to limit the scope of the present invention.

FIG. 1A to FIG. 1G illustrate a process of fabricating a light emitting device in some embodiments according to the present disclosure.

FIG. 2A to FIG. 2H illustrate a process of fabricating a light emitting device in some embodiments according to the present disclosure.

FIG. 3A to FIG. 3H illustrate a process of fabricating a light emitting device in some embodiments according to the present disclosure.

FIG. 4A to FIG. 4H illustrate a process of fabricating a light emitting device in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

One of the key steps in fabricating quantum dots display device is the patterning of the quantum dots layer. Currently, the patterning of the quantum dots layer can be realized by photolithography, printing, and transfer. Among these, printing is limited by the capabilities of the printing equipment, and it cannot achieve high Pixels Per Inch (PPI), and it also results in non-uniform film layers. Transfer techniques are not suitable for mass production equipment. On the other hand, photolithography offers the advantage of achieving high PPI and can be implemented using photolithography equipment, making it the subject of significant attention and research.

In some embodiments, peel-off photolithography may be used for patterning the quantum dots layer. Peel-off photolithography utilizes photoresist to create a pattern template. Subsequently, quantum dots are deposited within the entire area of the substrate covered with photoresist, followed by the removal of the photoresist through processes such as oxygen plasma etching or acetone washing, resulting in a pattern of quantum dots.

In some embodiments, quantum dots are directly mixed into photoresist, followed by patterning of the photoresist.

In some embodiments, ligand engineering lithography may be used for patterning the quantum dots layer. Ligand engineering lithography involves constructing photosensitive ligands for quantum dots, causing them to undergo photochemical reactions during the exposure process. This alteration in the solubility of quantum dots in the solvent achieves the lithographic patterning of quantum dots.

When a photoresist material is used, for example, either in the peel-off photolithography or when the quantum dots are directly mixed into photoresist, the introduction of non-conductive photoresist hinders charge injection. On the other hand, ligand engineering lithography presents an issue of quantum dot residue mixing.

Accordingly, the present disclosure provides, inter alia, a light emitting device and a display apparatus that substantially obviate one or more of the problems due to limitations and disadvantages of the related art. In one aspect, the present disclosure provides a light emitting device. In some embodiments, the light emitting device includes a first electrode; a second electrode; and a first functional layer, a first quantum dots layer of the first color, a first auxiliary quantum dots layer, and a second functional layer between the first electrode and the second electrode. Optionally, one or more first quantum dots of the first quantum dots layer of the first color is at least partially embedded in the first functional layer. Optionally, the first functional material in the first functional layer is at least partially cross-linked.

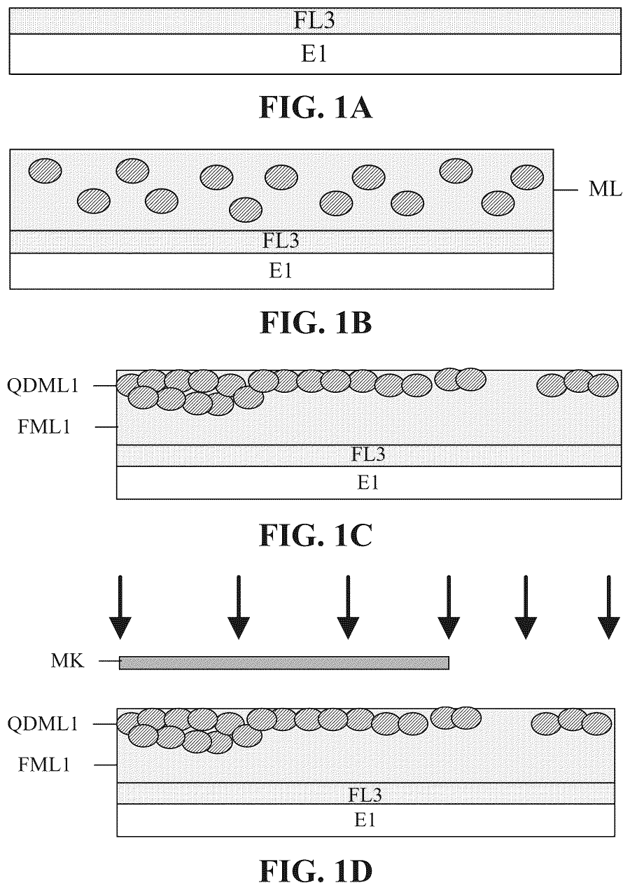

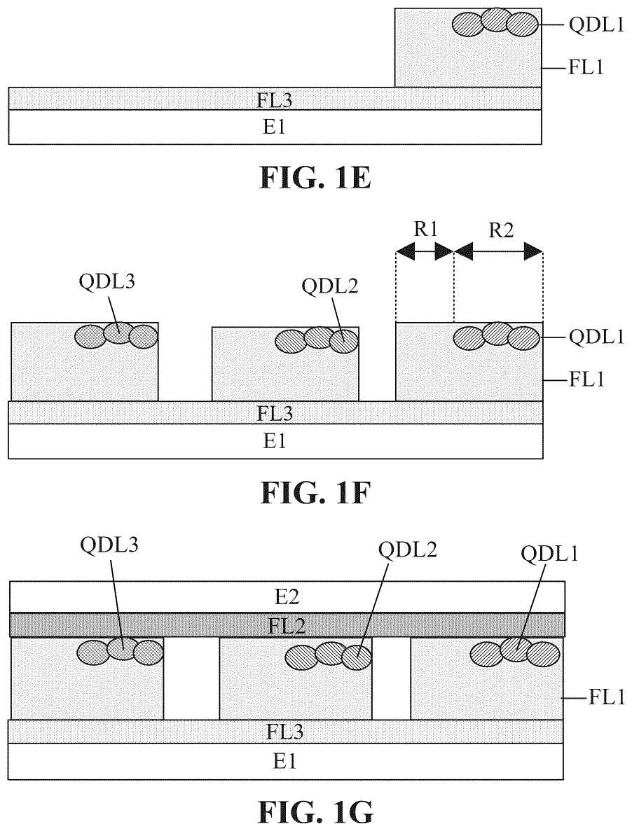

FIG. 1A to FIG. 1G illustrate a process of fabricating a light emitting device in some embodiments according to the present disclosure. Referring to FIG. 1A, a first electrode E1 is formed, and a third functional layer FL3 is formed on the first electrode E1.

Referring to FIG. 1B, a mixture layer ML is formed on a side of the third functional layer FL3 away from the first electrode E1. The mixture layer ML includes a first functional material, a first quantum dots material of a first color, and a photosensitizer. Optionally, the mixture layer ML further includes one or more solvents.

Various appropriate photosensitizers may be used in the present disclosure. Examples of photosensitizers include compounds that initiate cross-linking reactions when exposed to light. Specific examples of photosensitizers include benzoin derivatives, Irgacure 2959, Benzophenone, and Cinnamoyl Compounds. Photosensitizers such as benzoin derivatives, when exposed to ultraviolet (UV) or visible light, can undergo photolysis to produce free radicals. These free radicals can initiate crosslinking reactions in polymer systems or other photochemical processes. Examples of benzoin derivatives include N-isobutyl benzoin, benzoin methyl ether (BME), benzoin ethyl ether, benzoin isobutyl ether, and benzoin isobutyl ether acetate.

In some embodiments, the first functional material includes a carrier transport material. In some embodiments, the carrier transport material includes a hole transport material. In alternative embodiments, the carrier transport material includes an electron transport material.

In some embodiments, the first functional material includes a hole transport material, and the third functional layer FL3 is a hole injection layer.

In alternative embodiments, the first functional material includes an electron transport material, and the third functional layer FL3 is an electron injection layer.

In some embodiments, when the mixture layer ML is formed on a side of the third functional layer FL3 away from the first electrode E1, the first quantum dots material of the first color is dispersed in the solvent of the mixture layer ML.

Referring to FIG. 1C, the mixture layer ML is allowed to undergo a phase separation process during which the first quantum dots material of the first color segregates into a first quantum dots material layer QDML1. Upon segregation of the first quantum dots material of the first color into the first quantum dots material layer QDML1, the first functional material in the mixture layer ML forms a first functional material layer FML1.

In some embodiments, with respect to the first quantum dots material layer QDML1 and the first functional material layer FML1, a majority of the first quantum dots material (e.g., more than 50%, more than 60%, more than 70%, more than 80%, more than 90%, more than 95%, more than 99%, or 100%) is distributed in the first quantum dots material layer QDML1, and a minority of the first quantum dots material (e.g., less than 50%, less than 40%, less than 30%, less than 20%, less than 10%, less than 5%, less than 1%, or 0%) is distributed in the first functional material layer FML1.

In some embodiments, with respect to the first quantum dots material layer QDML1 and the first functional material layer FML1, a majority of the first functional material (e.g., more than 50%, more than 60%, more than 70%, more than 80%, more than 90%, more than 95%, more than 99%, or 100%) is distributed in the first functional material layer FML1, and a minority of the first functional material (e.g., less than 50%, less than 40%, less than 30%, less than 20%, less than 10%, less than 5%, less than 1%, or 0%) is distributed in the first quantum dots material layer QDML1.

In some embodiments, one or more first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1. In some embodiments, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1.

In some embodiments, at least a portion of the first functional material layer FML1 spaces apart the first quantum dots material layer QDML1 from the third functional layer FL3.

Referring to FIG. 1D, a mask plate MK is used to expose a first portion of the first functional material layer FML1 by light (e.g., a UV light or a visible light). In some embodiments, in the first portion of the first functional material layer FML1 that is exposed, the photosensitizer in the first portion of the first functional material layer FML1, upon exposure to the light, initiates crosslinking reactions among the first functional material in the first portion of the first functional material layer FML1. In a second portion of the first functional material layer FML1, the photosensitizer is not exposed to light due to the mask plate MK. The first functional material in the first portion of the first functional material layer FML1 and the first functional material in the second portion of the first functional material layer FML1 have different solubilities.

Referring to FIG. 1E, the first functional material layer is developed, e.g., using a developing solution. Due to the different solubilities of the first functional material in the first portion of the first functional material layer and the first functional material in the second portion of the first functional material layer, the second portion of the first functional material layer is removed along with a portion of the first quantum dots material layer in the same region, whereas the first portion of the first functional material layer and a portion of the first quantum dots material layer in the same region remain, thereby forming a first quantum dots layer QDL1 of the first color and at least a portion of a first functional layer FL1.

Referring to FIG. 1F, similar processes may be reiterated to form a second quantum dots layer QDL2 of a second color and a third quantum dots layer QDL3 of a third color. Referring to FIG. 1G, a second functional layer FL2 is formed on a side of the first quantum dots layer QDL1 of the first color, the second quantum dots layer QDL2 of the second color, and a third quantum dots layer QDL3 of the third color away from the first electrode E1. A second electrode E2 is formed on a side of the second functional layer FL2 away from the first functional layer FL1.

In some embodiments, the first functional layer FL1 includes a first functional material, and the second functional layer FL2 includes a second functional material.

In some embodiments, the first functional material includes a first carrier transport material, and the second functional material includes a second carrier transport material different from the first carrier transport material. In some embodiments, the first carrier transport material includes a hole transport material, and the second carrier transport material includes an electron transport material. Optionally, the first carrier transport material includes a hole transport material, the second carrier transport material includes an electron transport material, and the third functional layer FL3 is a hole injection layer. Optionally, the first carrier transport material includes a hole transport material, the second carrier transport material includes an electron transport material, the third functional layer FL3 is a hole injection layer, the first electrode E1 is an anode, and the second electrode E2 is a cathode. Optionally, light emitted from the light emitting device along a direction from the first electrode E1 to the second electrode E2.

In alternative embodiments, the first carrier transport material includes an electron transport material, and the second carrier transport material includes a hole transport material. Optionally, the first carrier transport material includes an electron transport material, the second carrier transport material includes a hole transport material, and the third functional layer FL3 is an electron injection layer. Optionally, the first carrier transport material includes an electron transport material, the second carrier transport material includes a hole transport material, the third functional layer FL3 is an electron injection layer, the first electrode E1 is a cathode, and the second electrode E2 is an anode. Optionally, light emitted from the light emitting device along a direction from the second electrode E2 to the first electrode E1.

Referring to FIG. 1G, the light emitting device in some embodiments includes a first electrode E1; a second electrode E2; and a first functional layer FL1, a first quantum dots layer QDL1 of the first color, and a second functional layer FL2 between the first electrode E1 and the second electrode E2. Optionally, the first quantum dots layer QDL1 of the first color is in contact with the first functional layer FL1 and in contact with the second functional layer FL2. In some embodiments, one or more first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the first quantum dots layer QDL1 of the first color and the first functional layer FL1, a majority of the first quantum dots material (e.g., more than 50%, more than 60%, more than 70%, more than 80%, more than 90%, more than 95%, more than 99%, or 100%) is distributed in the first quantum dots layer QDL1 of the first color, and a minority of the first quantum dots material (e.g., less than 50%, less than 40%, less than 30%, less than 20%, less than 10%, less than 5%, less than 1%, or 0%) is distributed in the first functional layer FL1.

In some embodiments, with respect to the first quantum dots layer QDL1 of the first color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the first quantum dots layer QDL1 of the first color.

In some embodiments, the first functional material in the first functional layer FL1 is at least partially (e.g., at least 10%, at least 20%, at least 30%, at least 40%, at least 50%, at least 60%, at least 70%, at least 80%, at least 90%, at least 95%, at least 99%, or 100%) cross-linked.

In some embodiments, the light emitting device further includes a second quantum dots layer QDL2 of the second color between the first electrode E1 and the second electrode E2. Optionally, the second quantum dots layer QDL2 of the second color is in contact with the first functional layer FL1 and in contact with the second functional layer FL2. In some embodiments, one or more second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the second quantum dots layer QDL2 of the second color and the first functional layer FL1, a majority of the second quantum dots material (e.g., more than 50%, more than 60%, more than 70%, more than 80%, more than 90%, more than 95%, more than 99%, or 100%) is distributed in the second quantum dots layer QDL2 of the second color, and a minority of the second quantum dots material (e.g., less than 50%, less than 40%, less than 30%, less than 20%, less than 10%, less than 5%, less than 1%, or 0%) is distributed in the first functional layer FL1.

In some embodiments, with respect to the second quantum dots layer QDL2 of the second color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the second quantum dots layer QDL2 of the second color.

In some embodiments, the light emitting device further includes a third quantum dots layer QDL3 of the third color between the first electrode E1 and the second electrode E2. Optionally, the third quantum dots layer QDL3 of the third color is in contact with the first functional layer FL1 and in contact with the second functional layer FL2. In some embodiments, one or more third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the third quantum dots layer QDL3 of the third color and the first functional layer FL1, a majority of the third quantum dots material (e.g., more than 50%, more than 60%, more than 70%, more than 80%, more than 90%, more than 95%, more than 99%, or 100%) is distributed in the third quantum dots layer QDL3 of the third color, and a minority of the third quantum dots material (e.g., less than 50%, less than 40%, less than 30%, less than 20%, less than 10%, less than 5%, less than 1%, or 0%) is distributed in the first functional layer FL1.

In some embodiments, with respect to the third quantum dots layer QDL3 of the third color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the third quantum dots layer QDL3 of the third color.

In some embodiments, the first color, the second color, and the third color are different from each other. Optionally, the first color, the second color, and the third color are three different colors selected from a red color, a green color, and a blue color.

The inventors of the present disclosure discover that, referring to FIG. 1A to FIG. 1G, during the phase separation of the mixture layer ML, the first quantum dots material is non-uniformly distributed. As a result, at least a portion of the first functional layer FL1 in a first region R1 is not covered by the first quantum dots layer QDL1 of the first color while another portion of the first functional layer FL1 in a second region R2 is covered by the first quantum dots layer QDL1 of the first color. At least a portion of the first functional layer FL1 in the first region R1 is in contact with the second functional layer FL2, leading to current leakage between the first functional layer FL1 and the second functional layer FL2, resulting in display defects.

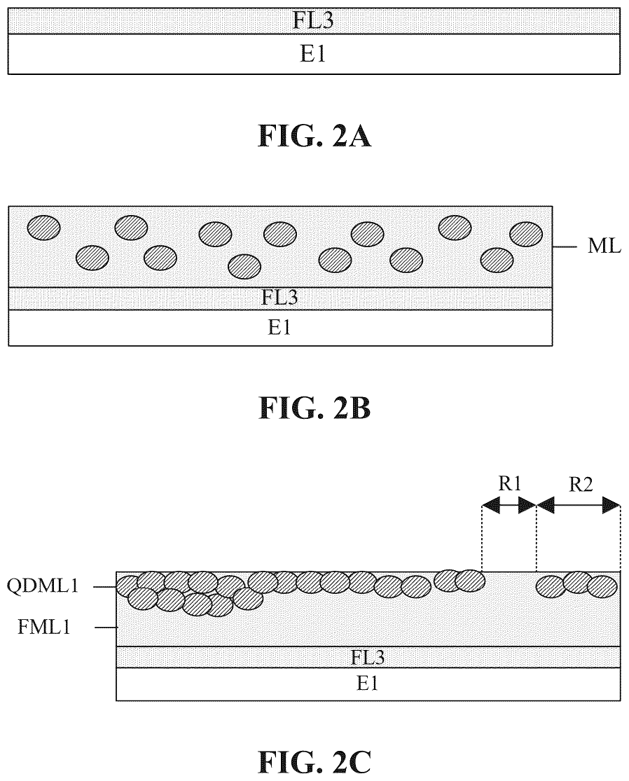

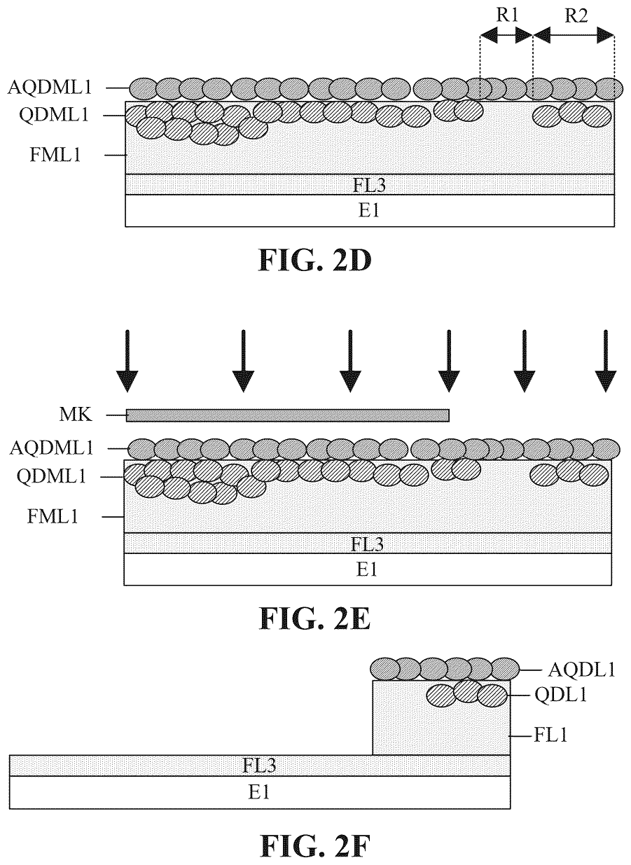

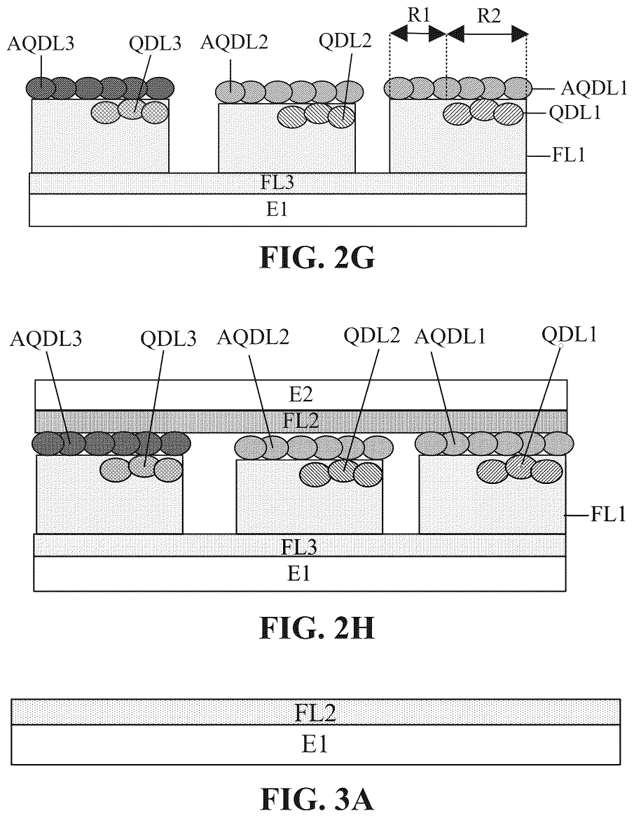

The inventors of the present disclosure discover that the light emitting device and the fabrication method according to the present disclosure can obviate the display defects. FIG. 2A to FIG. 2H illustrate a process of fabricating a light emitting device in some embodiments according to the present disclosure. Referring to FIG. 2A, a first electrode E1 is formed, and a third functional layer FL3 is formed on the first electrode E1.

Referring to FIG. 2B, a mixture layer ML is formed on a side of the third functional layer FL3 away from the first electrode E1. The mixture layer ML includes a first functional material, a first quantum dots material of a first color, and a photosensitizer. Optionally, the mixture layer ML further includes one or more solvents. In some embodiments, when the mixture layer ML is formed on a side of the third functional layer FL3 away from the first electrode E1, the first quantum dots material of the first color is dispersed in the solvent of the mixture layer ML.

Referring to FIG. 2C, the mixture layer ML is allowed to undergo a phase separation process during which the first quantum dots material of the first color segregates into a first quantum dots material layer QDML1. Upon segregation of the first quantum dots material of the first color into the first quantum dots material layer QDML1, the first functional material in the mixture layer ML forms a first functional material layer FML1. In FIG. 2C, at least a portion of the first functional material layer FML1 spaces apart the first quantum dots material layer QDML1 from the third functional layer FL3. The first quantum dots material layer QDML1 is on a side of the first functional material layer FML1 away from the first electrode E1.

In some embodiments, with respect to the first quantum dots material layer QDML1 and the first functional material layer FML1, a majority of the first quantum dots material (e.g., more than 50%, more than 60%, more than 70%, more than 80%, more than 90%, more than 95%, more than 99%, or 100%) is distributed in the first quantum dots material layer QDML1, and a minority of the first quantum dots material (e.g., less than 50%, less than 40%, less than 30%, less than 20%, less than 10%, less than 5%, less than 1%, or 0%) is distributed in the first functional material layer FML1.

In some embodiments, with respect to the first quantum dots material layer QDML1 and the first functional material layer FML1, a majority of the first functional material (e.g., more than 50%, more than 60%, more than 70%, more than 80%, more than 90%, more than 95%, more than 99%, or 100%) is distributed in the first functional material layer FML1, and a minority of the first functional material (e.g., less than 50%, less than 40%, less than 30%, less than 20%, less than 10%, less than 5%, less than 1%, or 0%) is distributed in the first quantum dots material layer QDML1.

In some embodiments, one or more first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1. In some embodiments, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1.

Referring to FIG. 2C, at least a portion of the first functional material layer FML1 in a first region R1 is not covered by the first quantum dots material layer QDML1 of the first color, while another portion of the first functional material layer FML1 in a second region R2 is covered by the first quantum dots material layer QDML1 of the first color. Optionally, an orthographic projection of a portion of the first functional material layer FML1 in a first region R1 on a base substrate is non-overlapping with an orthographic projection of the first quantum dots material layer QDML1 of the first color on the base substrate, and an orthographic projection of another portion of the first functional material layer FML1 in a second region R2 on the base substrate overlaps with the orthographic projection of the first quantum dots material layer QDML1 of the first color on the base substrate.

Referring to FIG. 2D, a first auxiliary quantum dots material layer AQDML1 of the first color is formed on a side of the first quantum dots material layer QDML1 and the first functional material layer FML1 away from the first electrode E1. Without the first auxiliary quantum dots material layer AQDML1 of the first color, as discussed in connection with FIG. 1A to FIG. 1G, in subsequent fabrication processes, the first functional material layer FML1 and the first quantum dots material layer QDML1 are patterned to form a first functional layer and a first quantum dots layer, and a second functional layer is formed on a side of the first functional layer and the first quantum dots layer away from the first electrode E1. Without the first auxiliary quantum dots material layer AQDML1 of the first color, at least a portion of the first functional layer in the first region R1 is in contact with the second functional layer, leading to current leakage between the first functional layer and the second functional layer, resulting in display defects.

In some embodiments, a first auxiliary quantum dots material of the first auxiliary quantum dots material layer AQDML1 of the first color extends substantially (e.g., at least 70%, at least 75%, at least 80%, at least 85%, at least 90%, at least 95%, at least 99%, or 100%) throughout the first region R1, preventing contact between the first functional layer and the second functional layer, improving display quality. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in a first region R1 on the base substrate.

In some embodiments, a combination of the first auxiliary quantum dots material of the first auxiliary quantum dots material layer AQDML1 of the first color and the first quantum dots material of the first quantum dots material layer QDML1 of the first color extends substantially (e.g., at least 70%, at least 75%, at least 80%, at least 85%, at least 90%, at least 95%, at least 99%, or 100%) throughout an entire region having the first functional material layer FML1. Optionally, an orthographic projection of a combination of the first auxiliary quantum dots material layer AQDML1 of the first color and the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of the first functional material layer FML1 on the base substrate.

In some embodiments, the first auxiliary quantum dots material of the first auxiliary quantum dots material layer AQDML1 of the first color extends substantially (e.g., at least 70%, at least 75%, at least 80%, at least 85%, at least 90%, at least 95%, at least 99%, or 100%) throughout an entire region having the first functional material layer FML1. Optionally, the first quantum dots material of the first quantum dots material layer QDML1 of the first color extends substantially (e.g., at least 70%, at least 75%, at least 80%, at least 85%, at least 90%, at least 95%, at least 99%, or 100%) throughout the second region R2. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of the first functional material layer FML1 on the base substrate. Optionally, an orthographic projection of the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in the second region R2 on the base substrate.

Referring to FIG. 2E, a mask plate MK is used to expose a first portion of the first functional material layer FML1 by light (e.g., a UV light or a visible light). In some embodiments, in the first portion of the first functional material layer FML1 that is exposed, the photosensitizer in the first portion of the first functional material layer FML1, upon exposure to the light, initiates crosslinking reactions among the first functional material in the first portion of the first functional material layer FML1. In a second portion of the first functional material layer FML1, the photosensitizer is not exposed to light due to the mask plate MK. The first functional material in the first portion of the first functional material layer FML1 and the first functional material in the second portion of the first functional material layer FML1 have different solubilities.

Referring to FIG. 2F, the first functional material layer is developed, e.g., using a developing solution. Due to the different solubilities of the first functional material in the first portion of the first functional material layer and the first functional material in the second portion of the first functional material layer, the second portion of the first functional material layer is removed along with a portion of the first quantum dots material layer in the same region and a portion of the first auxiliary quantum dots material layer in the same region, whereas the first portion of the first functional material layer, a portion of the first quantum dots material layer in the same region, and a portion of the first auxiliary quantum dots material layer in the same region remain, thereby forming a first quantum dots layer QDL1 of the first color, a first auxiliary quantum dots layer AQDL1 of the first color, and at least a portion of a first functional layer FL1.

Quantum dots materials in the first quantum dots layer QDL1 of the first color and the first auxiliary quantum dots layer AQDL1 of the first color are quantum dots materials of the same color, e.g., the first color. In some embodiments, quantum dots materials in the first quantum dots layer QDL1 of the first color are the same as quantum dots materials in the first auxiliary quantum dots layer AQDL1 of the first color. In alternative embodiments, quantum dots materials in the first quantum dots layer QDL1 of the first color are at least partially different from quantum dots materials in the first auxiliary quantum dots layer AQDL1 of the first color.

Referring to FIG. 2G, similar processes may be reiterated to form a second quantum dots layer QDL2 of a second color, a second auxiliary quantum dots layer AQDL2 of the second color, a third quantum dots layer QDL3 of a third color, and a third auxiliary quantum dots layer AQDL3 of the third color. Referring to FIG. 2H, a second functional layer FL2 is formed on a side of the first auxiliary quantum dots layer AQDL1 of the first color, the second auxiliary quantum dots layer AQDL2 of the second color, and a third auxiliary quantum dots layer AQDL3 of the third color away from the first electrode E1. A second electrode E2 is formed on a side of the second functional layer FL2 away from the first functional layer FL1.

In some embodiments, the light emitting device includes a first subpixel of the first color, a second subpixel of the second color, and a third subpixel of the third color. In some embodiments, the first subpixel of the first color includes the first quantum dots layer QDL1 and the first auxiliary quantum dots layer AQDL1; the second subpixel of the second color includes the second quantum dots layer QDL2 and the second auxiliary quantum dots layer AQDL2; and the third subpixel of the third color includes the third quantum dots layer QDL3 and the third auxiliary quantum dots layer AQDL3.

Quantum dots materials in the second quantum dots layer QDL2 of the second color and the second auxiliary quantum dots layer AQDL2 of the second color are quantum dots materials of the same color, e.g., the second color. In some embodiments, quantum dots materials in the second quantum dots layer QDL2 of the second color are the same as quantum dots materials in the second auxiliary quantum dots layer AQDL2 of the second color. In alternative embodiments, quantum dots materials in the second quantum dots layer QDL2 of the second color are at least partially different from quantum dots materials in the second auxiliary quantum dots layer AQDL2 of the second color.

Quantum dots materials in the third quantum dots layer QDL3 of the third color and the third auxiliary quantum dots layer AQDL3 of the third color are quantum dots materials of the same color, e.g., the third color. In some embodiments, quantum dots materials in the third quantum dots layer QDL3 of the third color are the same as quantum dots materials in the third auxiliary quantum dots layer AQDL3 of the third color. In alternative embodiments, quantum dots materials in the third quantum dots layer QDL3 of the third color are at least partially different from quantum dots materials in the third auxiliary quantum dots layer AQDL3 of the third color.

In some embodiments, a first auxiliary quantum dots material of the first auxiliary quantum dots layer AQDL1 of the first color extends substantially (e.g., at least 70%, at least 75%, at least 80%, at least 85%, at least 90%, at least 95%, at least 99%, or 100%) throughout the first region R1, preventing contact between the first functional layer FL1 and the second functional layer FL2, improving display quality. Optionally, the first quantum dots material of the first quantum dots layer QDL1 of the first color extends substantially (e.g., at least 70%, at least 75%, at least 80%, at least 85%, at least 90%, at least 95%, at least 99%, or 100%) throughout the second region R2.

In some embodiments, a combination of the first auxiliary quantum dots material of the first auxiliary quantum dots layer AQDL1 of the first color, the first quantum dots material of the first quantum dots layer QDL1 of the first color, the second auxiliary quantum dots material of the second auxiliary quantum dots layer AQDL2 of the second color, the second quantum dots material of the second quantum dots layer QDL2 of the second color, the third auxiliary quantum dots material of the third auxiliary quantum dots layer AQDL3 of the first color, and the third quantum dots material of the third quantum dots layer QDL3 of the third color extends substantially (e.g., at least 70%, at least 75%, at least 80%, at least 85%, at least 90%, at least 95%, at least 99%, or 100%) throughout an entire region having the first functional layer FL1.

In some embodiments, the first functional layer FL1 includes a first functional material, and the second functional layer FL2 includes a second functional material.

In some embodiments, the first functional material includes a first carrier transport material, and the second functional material includes a second carrier transport material different from the first carrier transport material. In some embodiments, the first carrier transport material includes a hole transport material, and the second carrier transport material includes an electron transport material. Optionally, the first carrier transport material includes a hole transport material, the second carrier transport material includes an electron transport material, and the third functional layer FL3 is a hole injection layer. Optionally, the first carrier transport material includes a hole transport material, the second carrier transport material includes an electron transport material, the third functional layer FL3 is a hole injection layer, the first electrode E1 is an anode, and the second electrode E2 is a cathode. Optionally, light emitted from the light emitting device along a direction from the first electrode E1 to the second electrode E2.

In alternative embodiments, the first carrier transport material includes an electron transport material, and the second carrier transport material includes a hole transport material. Optionally, the first carrier transport material includes an electron transport material, the second carrier transport material includes a hole transport material, and the third functional layer FL3 is an electron injection layer. Optionally, the first carrier transport material includes an electron transport material, the second carrier transport material includes a hole transport material, the third functional layer FL3 is an electron injection layer, the first electrode E1 is a cathode, and the second electrode E2 is an anode. Optionally, light emitted from the light emitting device along a direction from the second electrode E2 to the first electrode E1.

Referring to FIG. 2H, the light emitting device in some embodiments includes a first electrode E1; a second electrode E2; and a first functional layer FL1, a first quantum dots layer QDL1 of the first color, a first auxiliary quantum dots layer AQDL1, and a second functional layer FL2 between the first electrode E1 and the second electrode E2. Optionally, the first auxiliary quantum dots layer AQDL1 of the first color is in contact with the first functional layer FL1 and in contact with the second functional layer FL2. Optionally, the first auxiliary quantum dots layer AQDL1 of the first color is in contact with the first quantum dots layer QDL1 of the first color.

In some embodiments, one or more first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, the first auxiliary quantum dots layer AQDL1 is on a side of the first quantum dots layer QDL1 and the first functional layer FL1 away from the first electrode E1.

In some embodiments, with respect to the first quantum dots layer QDL1 of the first color and the first functional layer FL1, a majority of the first quantum dots material (e.g., more than 50%, more than 60%, more than 70%, more than 80%, more than 90%, more than 95%, more than 99%, or 100%) is distributed in the first quantum dots layer QDL1 of the first color, and a minority of the first quantum dots material (e.g., less than 50%, less than 40%, less than 30%, less than 20%, less than 10%, less than 5%, less than 1%, or 0%) is distributed in the first functional layer FL1.

In some embodiments, with respect to the first quantum dots layer QDL1 of the first color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the first quantum dots layer QDL1 of the first color.

In some embodiments, the first functional material in the first functional layer FL1 is at least partially (e.g., at least 10%, at least 20%, at least 30%, at least 40%, at least 50%, at least 60%, at least 70%, at least 80%, at least 90%, at least 95%, at least 99%, or 100%) cross-linked.

In some embodiments, an orthographic projection of the first auxiliary quantum dots layer AQDL1 on a base substrate substantially (e.g., at least 70%, at least 75%, at least 80%, at least 85%, at least 90%, at least 95%, at least 99%, or 100%) covers an orthographic projection of the first quantum dots layer QDL1 on the base substrate.

In some embodiments, the light emitting device further includes a second quantum dots layer QDL2 of the second color and a second auxiliary quantum dots layer AQDL2 between the first electrode E1 and the second electrode E2. Optionally, the second auxiliary quantum dots layer AQDL2 of the second color is in contact with the first functional layer FL1 and in contact with the second functional layer FL2. Optionally, the second auxiliary quantum dots layer AQDL2 of the second color is in contact with the second quantum dots layer QDL2 of the second color.

In some embodiments, one or more second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the second quantum dots layer QDL2 of the second color and the first functional layer FL1, a majority of the second quantum dots material (e.g., more than 50%, more than 60%, more than 70%, more than 80%, more than 90%, more than 95%, more than 99%, or 100%) is distributed in the second quantum dots layer QDL2 of the second color, and a minority of the second quantum dots material (e.g., less than 50%, less than 40%, less than 30%, less than 20%, less than 10%, less than 5%, less than 1%, or 0%) is distributed in the first functional layer FL1.

In some embodiments, with respect to the second quantum dots layer QDL2 of the second color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the second quantum dots layer QDL2 of the second color.

In some embodiments, an orthographic projection of the second auxiliary quantum dots layer AQDL2 on a base substrate substantially (e.g., at least 70%, at least 75%, at least 80%, at least 85%, at least 90%, at least 95%, at least 99%, or 100%) covers an orthographic projection of the second quantum dots layer QDL2 on the base substrate.

In some embodiments, the light emitting device further includes a third quantum dots layer QDL3 of the third color and a third auxiliary quantum dots layer AQDL3 between the first electrode E1 and the second electrode E2. Optionally, the third auxiliary quantum dots layer AQDL3 of the third color is in contact with the first functional layer FL1 and in contact with the second functional layer FL2. Optionally, the third auxiliary quantum dots layer AQDL3 of the third color is in contact with third quantum dots layer QDL3 of the third color.

In some embodiments, one or more third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the third quantum dots layer QDL3 of the third color and the first functional layer FL1, a majority of the third quantum dots material (e.g., more than 50%, more than 60%, more than 70%, more than 80%, more than 90%, more than 95%, more than 99%, or 100%) is distributed in the third quantum dots layer QDL3 of the third color, and a minority of the third quantum dots material (e.g., less than 50%, less than 40%, less than 30%, less than 20%, less than 10%, less than 5%, less than 1%, or 0%) is distributed in the first functional layer FL1.

In some embodiments, with respect to the third quantum dots layer QDL3 of the third color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the third quantum dots layer QDL3 of the third color.

In some embodiments, an orthographic projection of the third auxiliary quantum dots layer AQDL3 on a base substrate substantially (e.g., at least 70%, at least 75%, at least 80%, at least 85%, at least 90%, at least 95%, at least 99%, or 100%) covers an orthographic projection of the third quantum dots layer QDL3 on the base substrate.

In some embodiments, the first color, the second color, and the third color are different from each other. Optionally, the first color, the second color, and the third color are three different colors selected from a red color, a green color, and a blue color.

The inventors of the present disclosure discover that, referring to FIG. 2A to FIG. 2H, the presence of the auxiliary quantum dots layers (including the first auxiliary quantum dots layer AQDL1, the second auxiliary quantum dots layer AQDL2, and the third auxiliary quantum dots layer AQDL3) prevents the contact between the first functional layer FL1 and the second functional layer FL2, and the current leakage between the first functional layer FL1 and the second functional layer FL2, significantly improving display quality.

In some embodiments, quantum dots materials include an inorganic portion and a ligand. For example, the quantum dots materials in some embodiments include a shell, a core, and a ligand. The core and the shell, as used herein, may be referred to as QD core-shell, or QD core-shell structure, or core-shell structure. Examples of the materials for making the core-shell structure include Groups II-VI semiconductor compounds, Groups III-V semiconductor compounds, Groups IV-VI semiconductor compounds, Group IV semiconductor compounds, Groups I-III-VI semiconductor compounds, Groups I-II-IV-VI semiconductor compounds, and Groups II-III-V semiconductor compounds. The core-shell structure may be made of materials such as CdS, CdSe, CdTe, ZnSe, InP, PbS, CsPbCl3, CsPbBr3, CsPhI3, CsPbClxBr3−x, CsPbBrxI3−x, CdS/ZnS, CdSe/ZnS, ZnSe, ZnTeSe, ZnTe, InP/ZnS, PbS/ZnS, CsPbCl3/ZnS, CsPbBr3/ZnS, CsPhI3/ZnS, CsPbClxBr3−x/ZnS, CsPhBrxI3−x/ZnS, and combination(s) thereof, where x is a positive integer and x<3.

In some embodiments, quantum dots materials in the first quantum dots layer QDL1 of the first color include a first ligand, and quantum dots materials in the first auxiliary quantum dots layer AQDL1 of the first color include a first auxiliary ligand and a second auxiliary ligand. In some embodiments, ligands in the first quantum dots layer QDL1 of the first color have a same polarity. In some embodiments, the first auxiliary ligand and the second auxiliary ligand have different polarities.

In some embodiments, the first ligand includes a first binding group that binds to an inorganic portion of quantum dots materials in the first quantum dots layer QDL1 of the first color and a first tail connected to the first binding group; the first auxiliary ligand includes a first auxiliary binding group that binds to an inorganic portion of quantum dots materials in the first auxiliary quantum dots layer AQDL1 and a first auxiliary tail connected to the first auxiliary binding group; and the second auxiliary ligand includes a second auxiliary binding group that binds to an inorganic portion of quantum dots materials in the first auxiliary quantum dots layer AQDL1 and a second auxiliary tail connected to the second auxiliary binding group.

In some embodiments, the first tail has a first polarity, the first auxiliary tail has a second polarity, and the second auxiliary tail has a third polarity. In some embodiments, a difference between the first polarity and the second polarity is smaller than a difference between the first polarity and the third polarity. Polarity of a material may be measured by various appropriate methods. In one example, polarity is measured by dipole moment. In another example, a dipole moment between 0 Debye and 1 Debye is considered as non-polar, and a dipole moment equal to or greater than 1 Debye is considered as polar.

In some embodiments, the first tail is a non-polar group, the first auxiliary tail is a non-polar group, and the second auxiliary tail is a polar group. In one example, the first ligand is oleic acid. In another example, the first auxiliary ligand is oleic acid. In another example, the second auxiliary ligand is mono-2-(methacryloyloxy) ethyl succinate. In another example, the second auxiliary ligand is a ligand having a fluorinated group or a cyanide group.

In alternative embodiments, the first tail is a polar group, the first auxiliary tail is a polar group, and the second auxiliary tail is a non-polar group. In one example, the first ligand is mono-2-(methacryloyloxy) ethyl succinate. In another example, the first ligand is a ligand having a fluorinated group or a cyanide group. In another example, the first auxiliary ligand is mono-2-(methacryloyloxy) ethyl succinate. In another example, the first auxiliary ligand is a ligand having a fluorinated group or a cyanide group. In another example, the second auxiliary ligand is oleic acid.

In some embodiments, the mixture layer ML for forming the first quantum dots layer QDL1 includes a first solvent for dissolving the first quantum dots material, and a second solvent for dissolving the first functional material. In some embodiments, the first solvent and the second solvent have different polarities. In some embodiments, a difference between the first polarity of the first tail of the first ligand of quantum dots materials in the first quantum dots material and a polarity of the first solvent is smaller than a difference between the first polarity of the first tail of the first ligand of quantum dots materials in the first quantum dots material and a polarity of the second solvent.

In some embodiments, the first tail is a non-polar group, the first solvent is a non-polar solvent, and the second solvent is a polar solvent.

In alternative embodiments, the first tail is a polar group, the first solvent is a polar solvent, and the second solvent is a non-polar solvent.

In some embodiments, the first solvent has a first density, the second solvent has a second density. Optionally, the first density is different from the second density. In one example, the first density is smaller than the second density.

In one example, the mixture layer ML includes the first functional material, chlorobenzene, a quantum dots material having oleic acid as ligand, octane, mono-2-(methacryloyloxy) ethyl succinate, propylene glycol methyl ether acetate, and methanol. Subsequent to phase separation and drying, the first functional material layer FML1 includes the first functional material; and the first quantum dots material layer QDML1 includes the first quantum dots material having mono-2-(methacryloyloxy) ethyl succinate as the ligand.

In another example, the first auxiliary quantum dots material layer AQDML1 is formed by applying a solution including the first auxiliary quantum dots material having mono-2-(methacryloyloxy) ethyl succinate and oleic acid as the ligands, and propylene glycol methyl ether acetate as the solvent.

In some embodiments, quantum dots materials in the second quantum dots layer QDL2 of the second color include a second ligand, and quantum dots materials in the second auxiliary quantum dots layer AQDL2 of the second color include a third auxiliary ligand and a fourth auxiliary ligand. In some embodiments, ligands in the second quantum dots layer QDL2 of the second color have a same polarity. In some embodiments, the third auxiliary ligand and the fourth auxiliary ligand have different polarities.

In some embodiments, the second ligand includes a second binding group that binds to an inorganic portion of quantum dots materials in the second quantum dots layer QDL2 of the second color and a second tail connected to the second binding group; the third auxiliary ligand includes a third auxiliary binding group that binds to an inorganic portion of quantum dots materials in the second auxiliary quantum dots layer AQDL2 and a third auxiliary tail connected to the third auxiliary binding group; and the fourth auxiliary ligand includes a fourth auxiliary binding group that binds to an inorganic portion of quantum dots materials in the second auxiliary quantum dots layer AQDL2 and a fourth auxiliary tail connected to the fourth auxiliary binding group.

In some embodiments, the second tail has a fourth polarity, the third auxiliary tail has a fifth polarity, and the fourth auxiliary tail has a sixth polarity. In some embodiments, a difference between the fourth polarity and the fifth polarity is smaller than a difference between the fourth polarity and the sixth polarity.

In some embodiments, the second tail is a non-polar group, the third auxiliary tail is a non-polar group, and the fourth auxiliary tail is a polar group. In one example, the second ligand is oleic acid. In another example, the third auxiliary ligand is oleic acid. In another example, the fourth auxiliary ligand is mono-2-(methacryloyloxy) ethyl succinate. In another example, the fourth auxiliary ligand is a ligand having a fluorinated group or a cyanide group.

In alternative embodiments, the second tail is a polar group, the third auxiliary tail is a polar group, and the fourth auxiliary tail is a non-polar group. In one example, the second ligand is mono-2-(methacryloyloxy) ethyl succinate. In another example, the second ligand is a ligand having a fluorinated group or a cyanide group. In another example, the third auxiliary ligand is mono-2-(methacryloyloxy) ethyl succinate. In another example, the third auxiliary ligand is a ligand having a fluorinated group or a cyanide group. In another example, the fourth auxiliary ligand is oleic acid.

In some embodiments, the mixture layer ML for forming the second quantum dots layer QDL2 includes a third solvent for dissolving the second quantum dots material, and a fourth solvent for dissolving the first functional material. In some embodiments, the third solvent and the fourth solvent have different polarities. In some embodiments, a difference between the fourth polarity of the second tail of the second ligand of quantum dots materials in the second quantum dots material and a polarity of the third solvent is smaller than a difference between the fourth polarity of the second tail of the second ligand of quantum dots materials in the second quantum dots material and a polarity of the fourth solvent.

In some embodiments, the second tail is a non-polar group, the third solvent is a non-polar solvent, and the fourth solvent is a polar solvent.

In alternative embodiments, the second tail is a polar group, the third solvent is a polar solvent, and the fourth solvent is a non-polar solvent.

In some embodiments, the third solvent has a third density, the fourth solvent has a fourth density. Optionally, the third density is different from the fourth density. In one example, the third density is smaller than the fourth density.

In one example, the mixture layer ML includes the first functional material, chlorobenzene, a quantum dots material having oleic acid as ligand, octane, mono-2-(methacryloyloxy) ethyl succinate, propylene glycol methyl ether acetate, and methanol. Subsequent to phase separation and drying, the first functional material layer FML1 includes the first functional material; and the second quantum dots material layer includes the second quantum dots material having mono-2-(methacryloyloxy) ethyl succinate as the ligand.

In another example, the second auxiliary quantum dots material layer is formed by applying a solution including the second auxiliary quantum dots material having mono-2-(methacryloyloxy) ethyl succinate and oleic acid as the ligands, and propylene glycol methyl ether acetate as the solvent.

In some embodiments, quantum dots materials in the third quantum dots layer QDL3 of the third color include a third ligand, and quantum dots materials in the third auxiliary quantum dots layer AQDL3 of the third color include a fifth auxiliary ligand and a sixth auxiliary ligand. In some embodiments, ligands in the third quantum dots layer QDL3 of the third color have a same polarity. In some embodiments, the fifth auxiliary ligand and the sixth auxiliary ligand have different polarities.

In some embodiments, the third ligand includes a third binding group that binds to an inorganic portion of quantum dots materials in the third quantum dots layer QDL3 of the third color and a third tail connected to the third binding group; the fifth auxiliary ligand includes a fifth auxiliary binding group that binds to an inorganic portion of quantum dots materials in the third auxiliary quantum dots layer AQDL3 and a fifth auxiliary tail connected to the fifth auxiliary binding group; and the sixth auxiliary ligand includes a sixth auxiliary binding group that binds to an inorganic portion of quantum dots materials in the third auxiliary quantum dots layer AQDL3 and a sixth auxiliary tail connected to the sixth auxiliary binding group.

In some embodiments, the third tail has a seventh polarity, the fifth auxiliary tail has an eighth polarity, and the sixth auxiliary tail has a ninth polarity. In some embodiments, a difference between the seventh polarity and the eighth polarity is smaller than a difference between the seventh polarity and the ninth polarity.

In some embodiments, the third tail is a non-polar group, the fifth auxiliary tail is a non-polar group, and the sixth auxiliary tail is a polar group. In one example, the third ligand is oleic acid. In another example, the fifth auxiliary ligand is oleic acid. In another example, the sixth auxiliary ligand is mono-2-(methacryloyloxy) ethyl succinate. In another example, the sixth auxiliary ligand is a ligand having a fluorinated group or a cyanide group.

In alternative embodiments, the third tail is a polar group, the fifth auxiliary tail is a polar group, and the sixth auxiliary tail is a non-polar group. In one example, the third ligand is mono-2-(methacryloyloxy) ethyl succinate. In another example, the third ligand is a ligand having a fluorinated group or a cyanide group. In another example, the fifth auxiliary ligand is mono-2-(methacryloyloxy) ethyl succinate. In another example, the fifth auxiliary ligand is a ligand having a fluorinated group or a cyanide group. In another example, the sixth auxiliary ligand is oleic acid.

In some embodiments, the mixture layer ML for forming the third quantum dots layer QDL3 includes a fifth solvent for dissolving the third quantum dots material, and a sixth solvent for dissolving the first functional material. In some embodiments, the fifth solvent and the sixth solvent have different polarities. In some embodiments, a difference between the seventh polarity of the third tail of the third ligand of quantum dots materials in the third quantum dots material and a polarity of the fifth solvent is smaller than a difference between the seventh polarity of the third tail of the third ligand of quantum dots materials in the third quantum dots material and a polarity of the sixth solvent.

In some embodiments, the third tail is a non-polar group, the fifth solvent is a non-polar solvent, and the sixth solvent is a polar solvent.

In alternative embodiments, the third tail is a polar group, the fifth solvent is a polar solvent, and the sixth solvent is a non-polar solvent.

In some embodiments, the fifth solvent has a fifth density, the sixth solvent has a sixth density. Optionally, the fifth density is different from the sixth density. In one example, the fifth density is smaller than the sixth density.

In one example, the mixture layer ML includes the first functional material, chlorobenzene, a quantum dots material having oleic acid as ligand, octane, mono-2-(methacryloyloxy) ethyl succinate, propylene glycol methyl ether acetate, and methanol. Subsequent to phase separation and drying, the first functional material layer FML1 includes the first functional material; and the third quantum dots material layer includes the third quantum dots material having mono-2-(methacryloyloxy) ethyl succinate as the ligand.

In another example, the third auxiliary quantum dots material layer is formed by applying a solution including the third auxiliary quantum dots material having mono-2-(methacryloyloxy) ethyl succinate and oleic acid as the ligands, and propylene glycol methyl ether acetate as the solvent.

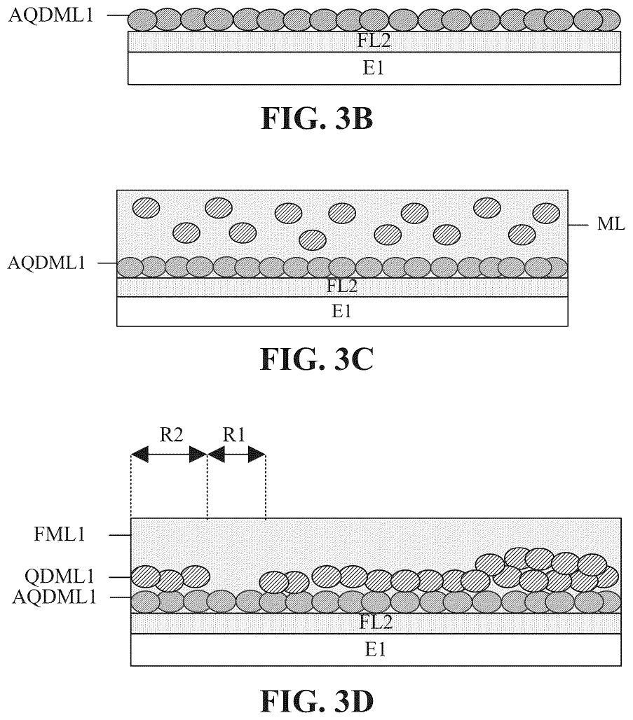

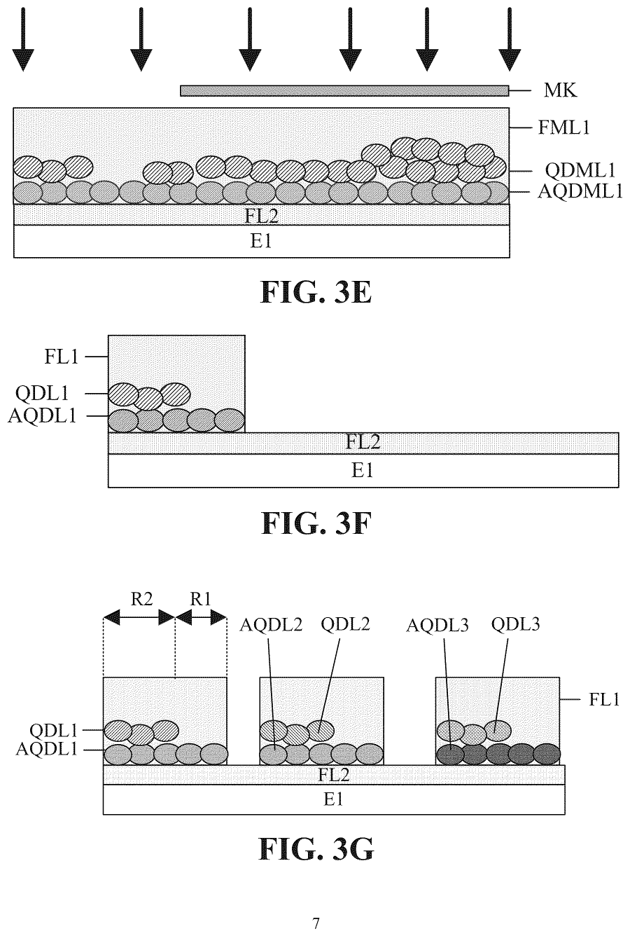

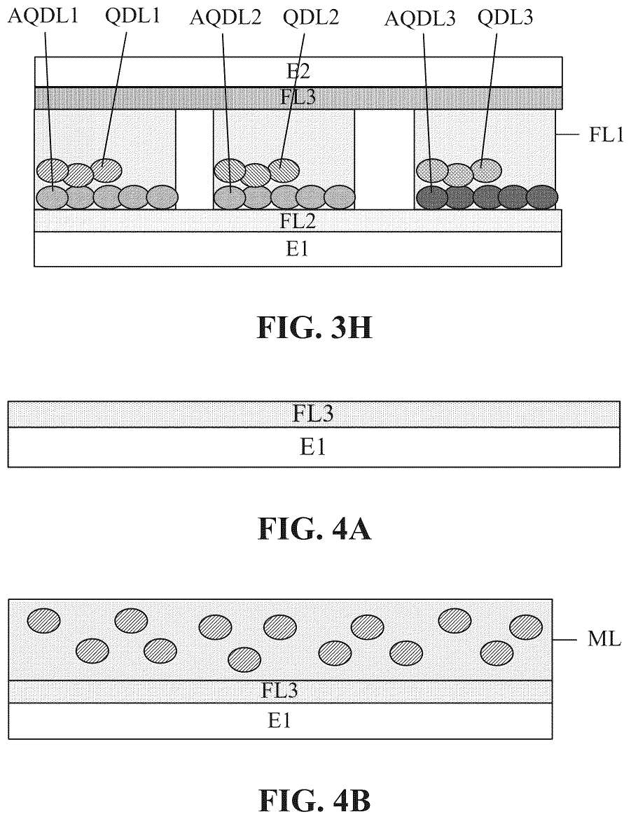

FIG. 3A to FIG. 3H illustrate a process of fabricating a light emitting device in some embodiments according to the present disclosure. Referring to FIG. 3A, a first electrode E1 is formed, and a second functional layer FL2 is formed on the first electrode E1.

Referring to FIG. 3B, a first auxiliary quantum dots material layer AQDML1 of the first color is formed on a side of the second functional layer FL2 away from the first electrode E1. In FIG. 3B, the first auxiliary quantum dots material layer AQDML1 of the first color is at least partially in contact with the second functional layer FL2.

Referring to FIG. 3C, a mixture layer ML is formed on a side of the first auxiliary quantum dots material layer AQDML1 of the first color away from the second functional layer FL2. The mixture layer ML includes a first functional material, a first quantum dots material of a first color, and a photosensitizer. Optionally, the mixture layer ML further includes one or more solvents. In some embodiments, when the mixture layer ML is formed on a side of the second functional layer FL2 away from the first electrode E1, the first quantum dots material of the first color is dispersed in the solvent of the mixture layer ML.

Referring to FIG. 3D, the mixture layer ML is allowed to undergo a phase separation process during which the first quantum dots material of the first color segregates into a first quantum dots material layer QDML1 of the first color. Upon segregation of the first quantum dots material of the first color into the first quantum dots material layer QDML1, the first functional material in the mixture layer ML forms a first functional material layer FML1. In FIG. 3D, the first quantum dots material layer QDML1 of the first color is at least partially in contact with the first auxiliary quantum dots material layer AQDML1 of the first color. The first functional material layer FML1 is on a side of the first quantum dots material layer QDML1 of the first color away from the first electrode E1.

In some embodiments, with respect to the first quantum dots material layer QDML1 and the first functional material layer FML1, a majority of the first quantum dots material (e.g., more than 50%, more than 60%, more than 70%, more than 80%, more than 90%, more than 95%, more than 99%, or 100%) is distributed in the first quantum dots material layer QDML1, and a minority of the first quantum dots material (e.g., less than 50%, less than 40%, less than 30%, less than 20%, less than 10%, less than 5%, less than 1%, or 0%) is distributed in the first functional material layer FML1.

In some embodiments, with respect to the first quantum dots material layer QDML1 and the first functional material layer FML1, a majority of the first functional material (e.g., more than 50%, more than 60%, more than 70%, more than 80%, more than 90%, more than 95%, more than 99%, or 100%) is distributed in the first functional material layer FML1, and a minority of the first functional material (e.g., less than 50%, less than 40%, less than 30%, less than 20%, less than 10%, less than 5%, less than 1%, or 0%) is distributed in the first quantum dots material layer QDML1.

In some embodiments, one or more first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1. In some embodiments, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1.

Referring to FIG. 3D, the first quantum dots material layer QDML1 of the first color is absent in a first region R1, and present in a second region R2. Optionally, an orthographic projection of a portion of the second functional layer FL2 in a first region R1 on a base substrate is non-overlapping with an orthographic projection of the first quantum dots material layer QDML1 of the first color on the base substrate, and an orthographic projection of another portion of the second functional layer FL2 in a second region R2 on the base substrate overlaps with the orthographic projection of the first quantum dots material layer QDML1 of the first color on the base substrate. Without the first auxiliary quantum dots material layer AQDML1 of the first color, at least a portion of the second functional layer FL2 in a first region R1 would not be covered by the first quantum dots material layer QDML1 of the first color, while another portion of the second functional layer FL2 in a second region R2 would be covered by the first quantum dots material layer QDML1 of the first color. Without the first auxiliary quantum dots material layer AQDML1 of the first color, the first functional material layer FML1 would be in contact with the second functional layer FL2. In subsequent fabrication processes, the first functional material layer FML1 and the first quantum dots material layer QDML1 are patterned to form a first functional layer and a first quantum dots layer. Without the first auxiliary quantum dots material layer AQDML1 of the first color, at least a portion of the first functional layer in the first region R1 is in contact with the second functional layer FL2, leading to current leakage between the first functional layer and the second functional layer FL2, resulting in display defects.

In some embodiments, a first auxiliary quantum dots material of the first auxiliary quantum dots material layer AQDML1 of the first color extends substantially (e.g., at least 70%, at least 75%, at least 80%, at least 85%, at least 90%, at least 95%, at least 99%, or 100%) throughout the first region R1, preventing contact between the first functional layer and the second functional layer, improving display quality. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in a first region R1 on the base substrate. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of a portion of the second functional layer FL2 in a first region R1 on the base substrate.

In some embodiments, a combination of the first auxiliary quantum dots material of the first auxiliary quantum dots material layer AQDML1 of the first color and the first quantum dots material of the first quantum dots material layer QDML1 of the first color extends substantially (e.g., at least 70%, at least 75%, at least 80%, at least 85%, at least 90%, at least 95%, at least 99%, or 100%) throughout an entire region having the first functional material layer FML1. Optionally, an orthographic projection of a combination of the first auxiliary quantum dots material layer AQDML1 of the first color and the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of the first functional material layer FML1 on the base substrate. In some embodiments, a combination of the first auxiliary quantum dots material of the first auxiliary quantum dots material layer AQDML1 of the first color and the first quantum dots material of the first quantum dots material layer QDML1 of the first color extends substantially (e.g., at least 70%, at least 75%, at least 80%, at least 85%, at least 90%, at least 95%, at least 99%, or 100%) throughout an entire region having the second functional layer FL2. Optionally, an orthographic projection of a combination of the first auxiliary quantum dots material layer AQDML1 of the first color and the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of the second functional layer FL2 on the base substrate.

In some embodiments, the first auxiliary quantum dots material of the first auxiliary quantum dots material layer AQDML1 of the first color extends substantially (e.g., at least 70%, at least 75%, at least 80%, at least 85%, at least 90%, at least 95%, at least 99%, or 100%) throughout an entire region having the first functional material layer FML1. Optionally, the first quantum dots material of the first quantum dots material layer QDML1 of the first color extends substantially (e.g., at least 70%, at least 75%, at least 80%, at least 85%, at least 90%, at least 95%, at least 99%, or 100%) throughout the second region R2. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of the first functional material layer FML1 on the base substrate. Optionally, an orthographic projection of the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in the second region R2 on the base substrate.

In some embodiments, the first auxiliary quantum dots material of the first auxiliary quantum dots material layer AQDML1 of the first color extends substantially (e.g., at least 70%, at least 75%, at least 80%, at least 85%, at least 90%, at least 95%, at least 99%, or 100%) throughout an entire region having the second functional layer FL2. Optionally, the first quantum dots material of the first quantum dots material layer QDML1 of the first color extends substantially (e.g., at least 70%, at least 75%, at least 80%, at least 85%, at least 90%, at least 95%, at least 99%, or 100%) throughout the second region R2. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of the second functional layer FL2 on the base substrate. Optionally, an orthographic projection of the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of a portion of the second functional layer FL2 in the second region R2 on the base substrate.

Referring to FIG. 3E, a mask plate MK is used to expose a first portion of the first functional material layer FML1 by light (e.g., a UV light or a visible light). In some embodiments, in the first portion of the first functional material layer FML1 that is exposed, the photosensitizer in the first portion of the first functional material layer FML1, upon exposure to the light, initiates crosslinking reactions among the first functional material in the first portion of the first functional material layer FML1. In a second portion of the first functional material layer FML1, the photosensitizer is not exposed to light due to the mask plate MK. The first functional material in the first portion of the first functional material layer FML1 and the first functional material in the second portion of the first functional material layer FML1 have different solubilities.

Referring to FIG. 3F, the first functional material layer is developed, e.g., using a developing solution. Due to the different solubilities of the first functional material in the first portion of the first functional material layer and the first functional material in the second portion of the first functional material layer, the second portion of the first functional material layer is removed along with a portion of the first quantum dots material layer in the same region and a portion of the first auxiliary quantum dots material layer in the same region, whereas the first portion of the first functional material layer, a portion of the first quantum dots material layer in the same region, and a portion of the first auxiliary quantum dots material layer in the same region remain, thereby forming a first quantum dots layer QDL1 of the first color, a first auxiliary quantum dots layer AQDL1 of the first color, and at least a portion of a first functional layer FL1.

Quantum dots materials in the first quantum dots layer QDL1 of the first color and the first auxiliary quantum dots layer AQDL1 of the first color are quantum dots materials of the same color, e.g., the first color. In some embodiments, quantum dots materials in the first quantum dots layer QDL1 of the first color are the same as quantum dots materials in the first auxiliary quantum dots layer AQDL1 of the first color. In alternative embodiments, quantum dots materials in the first quantum dots layer QDL1 of the first color are at least partially different from quantum dots materials in the first auxiliary quantum dots layer AQDL1 of the first color.

Referring to FIG. 3G, similar processes may be reiterated to form a second quantum dots layer QDL2 of a second color, a second auxiliary quantum dots layer AQDL2 of the second color, a third quantum dots layer QDL3 of a third color, and a third auxiliary quantum dots layer AQDL3 of the third color. Referring to FIG. 3H, a third functional layer FL3 is formed on a side of the first functional layer FL1 away from the first electrode E1. A second electrode E2 is formed on a side of the third functional layer FL3 away from the first functional layer FL1.

In some embodiments, the light emitting device includes a first subpixel of the first color, a second subpixel of the second color, and a third subpixel of the third color. In some embodiments, the first subpixel of the first color includes the first quantum dots layer QDL1 and the first auxiliary quantum dots layer AQDL1; the second subpixel of the second color includes the second quantum dots layer QDL2 and the second auxiliary quantum dots layer AQDL2; and the third subpixel of the third color includes the third quantum dots layer QDL3 and the third auxiliary quantum dots layer AQDL3.

Quantum dots materials in the second quantum dots layer QDL2 of the second color and the second auxiliary quantum dots layer AQDL2 of the second color are quantum dots materials of the same color, e.g., the second color. In some embodiments, quantum dots materials in the second quantum dots layer QDL2 of the second color are the same as quantum dots materials in the second auxiliary quantum dots layer AQDL2 of the second color. In alternative embodiments, quantum dots materials in the second quantum dots layer QDL2 of the second color are at least partially different from quantum dots materials in the second auxiliary quantum dots layer AQDL2 of the second color.

Quantum dots materials in the third quantum dots layer QDL3 of the third color and the third auxiliary quantum dots layer AQDL3 of the third color are quantum dots materials of the same color, e.g., the third color. In some embodiments, quantum dots materials in the third quantum dots layer QDL3 of the third color are the same as quantum dots materials in the third auxiliary quantum dots layer AQDL3 of the third color. In alternative embodiments, quantum dots materials in the third quantum dots layer QDL3 of the third color are at least partially different from quantum dots materials in the third auxiliary quantum dots layer AQDL3 of the third color.

In some embodiments, a first auxiliary quantum dots material of the first auxiliary quantum dots layer AQDL1 of the first color extends substantially (e.g., at least 70%, at least 75%, at least 80%, at least 85%, at least 90%, at least 95%, at least 99%, or 100%) throughout the first region R1, preventing contact between the first functional layer FL1 and the second functional layer FL2, improving display quality. Optionally, the first quantum dots material of the first quantum dots layer QDL1 of the first color extends substantially (e.g., at least 70%, at least 75%, at least 80%, at least 85%, at least 90%, at least 95%, at least 99%, or 100%) throughout the second region R2.

In some embodiments, a combination of the first auxiliary quantum dots material of the first auxiliary quantum dots layer AQDL1 of the first color, the first quantum dots material of the first quantum dots layer QDL1 of the first color, the second auxiliary quantum dots material of the second auxiliary quantum dots layer AQDL2 of the second color, the second quantum dots material of the second quantum dots layer QDL2 of the second color, the third auxiliary quantum dots material of the third auxiliary quantum dots layer AQDL3 of the first color, and the third quantum dots material of the third quantum dots layer QDL3 of the third color extends substantially (e.g., at least 70%, at least 75%, at least 80%, at least 85%, at least 90%, at least 95%, at least 99%, or 100%) throughout an entire region having the first functional layer FL1.

In some embodiments, the first functional layer FL1 includes a first functional material, and the second functional layer FL2 includes a second functional material.

In some embodiments, the first functional material includes a first carrier transport material, and the second functional material includes a second carrier transport material different from the first carrier transport material. In some embodiments, the first carrier transport material includes a hole transport material, and the second carrier transport material includes an electron transport material. Optionally, the first carrier transport material includes a hole transport material, the second carrier transport material includes an electron transport material, and the third functional layer FL3 is a hole injection layer. Optionally, the first carrier transport material includes a hole transport material, the second carrier transport material includes an electron transport material, the third functional layer FL3 is a hole injection layer, the first electrode E1 is an anode, and the second electrode E2 is a cathode. Optionally, light emitted from the light emitting device along a direction from the first electrode E1 to the second electrode E2.

In alternative embodiments, the first carrier transport material includes an electron transport material, and the second carrier transport material includes a hole transport material. Optionally, the first carrier transport material includes an electron transport material, the second carrier transport material includes a hole transport material, and the third functional layer FL3 is an electron injection layer. Optionally, the first carrier transport material includes an electron transport material, the second carrier transport material includes a hole transport material, the third functional layer FL3 is an electron injection layer, the first electrode E1 is a cathode, and the second electrode E2 is an anode. Optionally, light emitted from the light emitting device along a direction from the second electrode E2 to the first electrode E1.

Referring to FIG. 3H, the light emitting device in some embodiments includes a first electrode E1; a second electrode E2; and a first functional layer FL1, a first quantum dots layer QDL1 of the first color, a first auxiliary quantum dots layer AQDL1, and a second functional layer FL2 between the first electrode E1 and the second electrode E2. Optionally, the first auxiliary quantum dots layer AQDL1 of the first color is in contact with the first functional layer FL1 and in contact with the second functional layer FL2. Optionally, the first auxiliary quantum dots layer AQDL1 of the first color is in contact with the first quantum dots layer QDL1 of the first color.

In some embodiments, one or more first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, one or more first auxiliary quantum dots of the first auxiliary quantum dots layer AQDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the first auxiliary quantum dots of the first auxiliary quantum dots layer AQDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, the first quantum dots layer QDL1 is on a side of the first auxiliary quantum dots layer AQDL1 and the second functional layer FL2 away from the first electrode E1.

In some embodiments, with respect to the first quantum dots layer QDL1 of the first color and the first functional layer FL1, a majority of the first quantum dots material (e.g., more than 50%, more than 60%, more than 70%, more than 80%, more than 90%, more than 95%, more than 99%, or 100%) is distributed in the first quantum dots layer QDL1 of the first color, and a minority of the first quantum dots material (e.g., less than 50%, less than 40%, less than 30%, less than 20%, less than 10%, less than 5%, less than 1%, or 0%) is distributed in the first functional layer FL1.

In some embodiments, with respect to the first quantum dots layer QDL1 of the first color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the first quantum dots layer QDL1 of the first color.

In some embodiments, the first functional material in the first functional layer FL1 is at least partially (e.g., at least 10%, at least 20%, at least 30%, at least 40%, at least 50%, at least 60%, at least 70%, at least 80%, at least 90%, at least 95%, at least 99%, or 100%) cross-linked.

In some embodiments, an orthographic projection of the first auxiliary quantum dots layer AQDL1 on a base substrate substantially (e.g., at least 70%, at least 75%, at least 80%, at least 85%, at least 90%, at least 95%, at least 99%, or 100%) covers an orthographic projection of the first quantum dots layer QDL1 on the base substrate.

In some embodiments, the light emitting device further includes a second quantum dots layer QDL2 of the second color and a second auxiliary quantum dots layer AQDL2 between the first electrode E1 and the second electrode E2. Optionally, the second auxiliary quantum dots layer AQDL2 of the second color is in contact with the first functional layer FL1 and in contact with the second functional layer FL2. Optionally, the second auxiliary quantum dots layer AQDL2 of the second color is in contact with the second quantum dots layer QDL2 of the second color.

In some embodiments, one or more second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, one or more second auxiliary quantum dots of the second auxiliary quantum dots layer AQDL2 of the second color is at least partially (e.g., at least 10%), at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the second auxiliary quantum dots of the second auxiliary quantum dots layer AQDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the second quantum dots layer QDL2 of the second color and the first functional layer FL1, a majority of the second quantum dots material (e.g., more than 50%, more than 60%, more than 70%, more than 80%, more than 90%, more than 95%, more than 99%, or 100%) is distributed in the second quantum dots layer QDL2 of the second color, and a minority of the second quantum dots material (e.g., less than 50%, less than 40%, less than 30%, less than 20%, less than 10%, less than 5%, less than 1%, or 0%) is distributed in the first functional layer FL1.

In some embodiments, with respect to the second quantum dots layer QDL2 of the second color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the second quantum dots layer QDL2 of the second color.

In some embodiments, an orthographic projection of the second auxiliary quantum dots layer AQDL2 on a base substrate substantially (e.g., at least 70%, at least 75%, at least 80%, at least 85%, at least 90%, at least 95%, at least 99%, or 100%) covers an orthographic projection of the second quantum dots layer QDL2 on the base substrate.

In some embodiments, the light emitting device further includes a third quantum dots layer QDL3 of the third color and a third auxiliary quantum dots layer AQDL3 between the first electrode E1 and the second electrode E2. Optionally, the third auxiliary quantum dots layer AQDL3 of the third color is in contact with the first functional layer FL1 and in contact with the second functional layer FL2. Optionally, the third auxiliary quantum dots layer AQDL3 of the third color is in contact with third quantum dots layer QDL3 of the third color.

In some embodiments, one or more third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, one or more third auxiliary quantum dots of the third auxiliary quantum dots layer AQDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the third auxiliary quantum dots of the third auxiliary quantum dots layer AQDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the third quantum dots layer QDL3 of the third color and the first functional layer FL1, a majority of the third quantum dots material (e.g., more than 50%, more than 60%, more than 70%, more than 80%, more than 90%, more than 95%, more than 99%, or 100%) is distributed in the third quantum dots layer QDL3 of the third color, and a minority of the third quantum dots material (e.g., less than 50%, less than 40%, less than 30%, less than 20%, less than 10%, less than 5%, less than 1%, or 0%) is distributed in the first functional layer FL1.

In some embodiments, with respect to the third quantum dots layer QDL3 of the third color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the third quantum dots layer QDL3 of the third color.

In some embodiments, an orthographic projection of the third auxiliary quantum dots layer AQDL3 on a base substrate substantially (e.g., at least 70%, at least 75%, at least 80%, at least 85%, at least 90%, at least 95%, at least 99%, or 100%) covers an orthographic projection of the third quantum dots layer QDL3 on the base substrate.

In some embodiments, the first color, the second color, and the third color are different from each other. Optionally, the first color, the second color, and the third color are three different colors selected from a red color, a green color, and a blue color.

The inventors of the present disclosure discover that, referring to FIG. 3A to FIG. 3H, the presence of the auxiliary quantum dots layers (including the first auxiliary quantum dots layer AQDL1, the second auxiliary quantum dots layer AQDL2, and the third auxiliary quantum dots layer AQDL3) prevents the contact between the first functional layer FL1 and the second functional layer FL2, and the current leakage between the first functional layer FL1 and the second functional layer FL2, significantly improving display quality.

In some embodiments, quantum dots materials include an inorganic portion and a ligand. For example, the quantum dots materials in some embodiments include a shell, a core, and a ligand. The core and the shell, as used herein, may be referred to as QD core-shell, or QD core-shell structure, or core-shell structure. The core-shell structure may be made of materials such as CdS, CdSe, CdTe, ZnSe, InP, PbS, CsPbCl3, CsPbBr3, CsPhI3, CsPbClxBr3−x, CsPbBrxI3−x, CdS/ZnS, CdSe/ZnS, ZnSe, InP/ZnS, PbS/ZnS, CsPbCl3/ZnS, CsPbBr3/ZnS, CsPhI3/ZnS, CsPbClxBr3−x/ZnS, CsPhBrxI3−x/ZnS, and combination(s) thereof, where x is a positive integer and x<3.

In some embodiments, quantum dots materials in the first quantum dots layer QDL1 of the first color include a first ligand, and quantum dots materials in the first auxiliary quantum dots layer AQDL1 of the first color include a first auxiliary ligand and a second auxiliary ligand. In some embodiments, ligands in the first quantum dots layer QDL1 of the first color have a same polarity. In some embodiments, the first auxiliary ligand and the second auxiliary ligand have different polarities.

In some embodiments, the first ligand includes a first binding group that binds to an inorganic portion of quantum dots materials in the first quantum dots layer QDL1 of the first color and a first tail connected to the first binding group; the first auxiliary ligand includes a first auxiliary binding group that binds to an inorganic portion of quantum dots materials in the first auxiliary quantum dots layer AQDL1 and a first auxiliary tail connected to the first auxiliary binding group; and the second auxiliary ligand includes a second auxiliary binding group that binds to an inorganic portion of quantum dots materials in the first auxiliary quantum dots layer AQDL1 and a second auxiliary tail connected to the second auxiliary binding group.

In some embodiments, the first tail has a first polarity, the first auxiliary tail has a second polarity, and the second auxiliary tail has a third polarity. In some embodiments, a difference between the first polarity and the second polarity is smaller than a difference between the first polarity and the third polarity. Polarity of a material may be measured by various appropriate methods. In one example, polarity is measured by dipole moment. In another example, a dipole moment between 0 Debye and 1 Debye is considered as non-polar, and a dipole moment equal to or greater than 1 Debye is considered as polar.

In some embodiments, the first tail is a non-polar group, the first auxiliary tail is a non-polar group, and the second auxiliary tail is a polar group. In one example, the first ligand is oleic acid. In another example, the first auxiliary ligand is oleic acid. In another example, the second auxiliary ligand is mono-2-(methacryloyloxy) ethyl succinate. In another example, the second auxiliary ligand is a ligand having a fluorinated group or a cyanide group.

In alternative embodiments, the first tail is a polar group, the first auxiliary tail is a polar group, and the second auxiliary tail is a non-polar group. In one example, the first ligand is mono-2-(methacryloyloxy) ethyl succinate. In another example, the first ligand is a ligand having a fluorinated group or a cyanide group. In another example, the first auxiliary ligand is mono-2-(methacryloyloxy) ethyl succinate. In another example, the first auxiliary ligand is a ligand having a fluorinated group or a cyanide group. In another example, the second auxiliary ligand is oleic acid.

In some embodiments, the mixture layer ML for forming the first quantum dots layer QDL1 includes a first solvent for dissolving the first quantum dots material, and a second solvent for dissolving the first functional material. In some embodiments, the first solvent and the second solvent have different polarities. In some embodiments, a difference between the first polarity of the first tail of the first ligand of quantum dots materials in the first quantum dots material and a polarity of the first solvent is smaller than a difference between the first polarity of the first tail of the first ligand of quantum dots materials in the first quantum dots material and a polarity of the second solvent.

In some embodiments, the first tail is a non-polar group, the first solvent is a non-polar solvent, and the second solvent is a polar solvent.

In alternative embodiments, the first tail is a polar group, the first solvent is a polar solvent, and the second solvent is a non-polar solvent.

In some embodiments, the first solvent has a first density, the second solvent has a second density. Optionally, the first density is different from the second density. In one example, the first density is smaller than the second density.

In one example, the mixture layer ML includes the first functional material, chlorobenzene, a quantum dots material having oleic acid as ligand, and octane. Because chlorobenzene and octane have different polarities and different densities, use of chlorobenzene and octane as solvents facilitates phase separation. Subsequent to phase separation and drying, the first functional material layer FML1 includes the first functional material; and the first quantum dots material layer QDML1 includes the first quantum dots material having oleic acid as the ligand.

In another example, the first auxiliary quantum dots material layer AQDML1 is formed by applying a solution including the first auxiliary quantum dots material having mono-2-(methacryloyloxy) ethyl succinate and oleic acid as the ligands, and propylene glycol methyl ether acetate as the solvent.

In some embodiments, quantum dots materials in the second quantum dots layer QDL2 of the second color include a second ligand, and quantum dots materials in the second auxiliary quantum dots layer AQDL2 of the second color include a third auxiliary ligand and a fourth auxiliary ligand. In some embodiments, ligands in the second quantum dots layer QDL2 of the second color have a same polarity. In some embodiments, the third auxiliary ligand and the fourth auxiliary ligand have different polarities.

In some embodiments, the second ligand includes a second binding group that binds to an inorganic portion of quantum dots materials in the second quantum dots layer QDL2 of the second color and a second tail connected to the second binding group; the third auxiliary ligand includes a third auxiliary binding group that binds to an inorganic portion of quantum dots materials in the second auxiliary quantum dots layer AQDL2 and a third auxiliary tail connected to the third auxiliary binding group; and the fourth auxiliary ligand includes a fourth auxiliary binding group that binds to an inorganic portion of quantum dots materials in the second auxiliary quantum dots layer AQDL2 and a fourth auxiliary tail connected to the fourth auxiliary binding group.

In some embodiments, the second tail has a fourth polarity, the third auxiliary tail has a fifth polarity, and the fourth auxiliary tail has a sixth polarity. In some embodiments, a difference between the fourth polarity and the fifth polarity is smaller than a difference between the fourth polarity and the sixth polarity.

In some embodiments, the second tail is a non-polar group, the third auxiliary tail is a non-polar group, and the fourth auxiliary tail is a polar group. In one example, the second ligand is oleic acid. In another example, the third auxiliary ligand is oleic acid. In another example, the fourth auxiliary ligand is mono-2-(methacryloyloxy) ethyl succinate. In another example, the fourth auxiliary ligand is a ligand having a fluorinated group or a cyanide group.

In alternative embodiments, the second tail is a polar group, the third auxiliary tail is a polar group, and the fourth auxiliary tail is a non-polar group. In one example, the second ligand is mono-2-(methacryloyloxy) ethyl succinate. In another example, the second ligand is a ligand having a fluorinated group or a cyanide group. In another example, the third auxiliary ligand is mono-2-(methacryloyloxy) ethyl succinate. In another example, the third auxiliary ligand is a ligand having a fluorinated group or a cyanide group. In another example, the fourth auxiliary ligand is oleic acid.

In some embodiments, the mixture layer ML for forming the second quantum dots layer QDL2 includes a third solvent for dissolving the second quantum dots material, and a fourth solvent for dissolving the first functional material. In some embodiments, the third solvent and the fourth solvent have different polarities. In some embodiments, a difference between the fourth polarity of the second tail of the second ligand of quantum dots materials in the second quantum dots material and a polarity of the third solvent is smaller than a difference between the fourth polarity of the second tail of the second ligand of quantum dots materials in the second quantum dots material and a polarity of the fourth solvent.

In some embodiments, the second tail is a non-polar group, the third solvent is a non-polar solvent, and the fourth solvent is a polar solvent.

In alternative embodiments, the second tail is a polar group, the third solvent is a polar solvent, and the fourth solvent is a non-polar solvent.

In some embodiments, the third solvent has a third density, the fourth solvent has a fourth density. Optionally, the third density is different from the fourth density. In one example, the third density is smaller than the fourth density.

In one example, the mixture layer ML includes the first functional material, chlorobenzene, a quantum dots material having oleic acid as ligand, and octane. Because chlorobenzene and octane have different polarities and different densities, use of chlorobenzene and octane as solvents facilitates phase separation. Subsequent to phase separation and drying, the first functional material layer FML1 includes the first functional material; and the second quantum dots material layer includes the second quantum dots material having oleic acid as the ligand.

In another example, the second auxiliary quantum dots material layer is formed by applying a solution including the second auxiliary quantum dots material having mono-2-(methacryloyloxy) ethyl succinate and oleic acid as the ligands, and propylene glycol methyl ether acetate as the solvent.

In some embodiments, quantum dots materials in the third quantum dots layer QDL3 of the third color include a third ligand, and quantum dots materials in the third auxiliary quantum dots layer AQDL3 of the third color include a fifth auxiliary ligand and a sixth auxiliary ligand. In some embodiments, ligands in the third quantum dots layer QDL3 of the third color have a same polarity. In some embodiments, the fifth auxiliary ligand and the sixth auxiliary ligand have different polarities.

In some embodiments, the third ligand includes a third binding group that binds to an inorganic portion of quantum dots materials in the third quantum dots layer QDL3 of the third color and a third tail connected to the third binding group; the fifth auxiliary ligand includes a fifth auxiliary binding group that binds to an inorganic portion of quantum dots materials in the third auxiliary quantum dots layer AQDL3 and a fifth auxiliary tail connected to the fifth auxiliary binding group; and the sixth auxiliary ligand includes a sixth auxiliary binding group that binds to an inorganic portion of quantum dots materials in the third auxiliary quantum dots layer AQDL3 and a sixth auxiliary tail connected to the sixth auxiliary binding group.

In some embodiments, the third tail has a seventh polarity, the fifth auxiliary tail has an eighth polarity, and the sixth auxiliary tail has a ninth polarity. In some embodiments, a difference between the seventh polarity and the eighth polarity is smaller than a difference between the seventh polarity and the ninth polarity.

In some embodiments, the third tail is a non-polar group, the fifth auxiliary tail is a non-polar group, and the sixth auxiliary tail is a polar group. In one example, the third ligand is oleic acid. In another example, the fifth auxiliary ligand is oleic acid. In another example, the sixth auxiliary ligand is mono-2-(methacryloyloxy) ethyl succinate. In another example, the sixth auxiliary ligand is a ligand having a fluorinated group or a cyanide group.

In alternative embodiments, the third tail is a polar group, the fifth auxiliary tail is a polar group, and the sixth auxiliary tail is a non-polar group. In one example, the third ligand is mono-2-(methacryloyloxy) ethyl succinate. In another example, the third ligand is a ligand having a fluorinated group or a cyanide group. In another example, the fifth auxiliary ligand is mono-2-(methacryloyloxy) ethyl succinate. In another example, the fifth auxiliary ligand is a ligand having a fluorinated group or a cyanide group. In another example, the sixth auxiliary ligand is oleic acid.

In some embodiments, the mixture layer ML for forming the third quantum dots layer QDL3 includes a fifth solvent for dissolving the third quantum dots material, and a sixth solvent for dissolving the first functional material. In some embodiments, the fifth solvent and the sixth solvent have different polarities. In some embodiments, a difference between the seventh polarity of the third tail of the third ligand of quantum dots materials in the third quantum dots material and a polarity of the fifth solvent is smaller than a difference between the seventh polarity of the third tail of the third ligand of quantum dots materials in the third quantum dots material and a polarity of the sixth solvent.

In some embodiments, the third tail is a non-polar group, the fifth solvent is a non-polar solvent, and the sixth solvent is a polar solvent.

In alternative embodiments, the third tail is a polar group, the fifth solvent is a polar solvent, and the sixth solvent is a non-polar solvent.

In some embodiments, the fifth solvent has a fifth density, the sixth solvent has a sixth density. Optionally, the fifth density is different from the sixth density. In one example, the fifth density is smaller than the sixth density.

In one example, the mixture layer ML includes the first functional material, chlorobenzene, a quantum dots material having oleic acid as ligand, and octane. Because chlorobenzene and octane have different polarities and different densities, use of chlorobenzene and octane as solvents facilitates phase separation. Subsequent to phase separation and drying, the first functional material layer FML1 includes the first functional material; and the third quantum dots material layer includes the third quantum dots material having oleic acid as the ligand.

In another example, the third auxiliary quantum dots material layer is formed by applying a solution including the third auxiliary quantum dots material having mono-2-(methacryloyloxy) ethyl succinate and oleic acid as the ligands, and propylene glycol methyl ether acetate as the solvent.

Referring to FIG. 2A to FIG. 2H, and FIG. 3A to FIG. 3H, in some embodiments, the first quantum dots layer QDL1 has a non-uniform thickness. For example, the non-uniform thickness may refer to that the thickness varies by a difference of at least a thickness (e.g., twice the thickness, at least 5 times the thickness, at least 10 times the thickness, at least 15 times the thickness, or at least 20 times the thickness) of one quantum dots. In another example, the non-uniform thickness may refer to that the thickness varies by a difference of at least 2 nm, e.g., at least 5 nm, at least 10 nm, at least 15 nm, or at least 20 nm. In some embodiments, a combination of the first quantum dots layer QDL1 and the first auxiliary quantum dots layer AQDL1 has a non-uniform thickness. In some embodiments, the second quantum dots layer QDL2 has a non-uniform thickness. In some embodiments, a combination of the second quantum dots layer QDL2 and the second auxiliary quantum dots layer AQDL2 has a non-uniform thickness. In some embodiments, the third quantum dots layer QDL3 has a non-uniform thickness. In some embodiments, a combination of the third quantum dots layer QDL3 and the third auxiliary quantum dots layer AQDL3 has a non-uniform thickness.

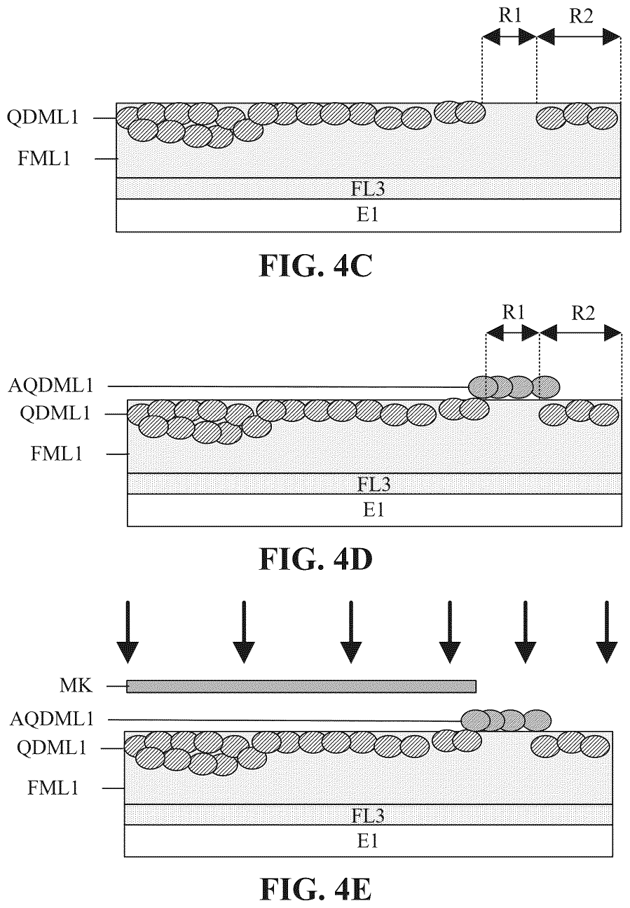

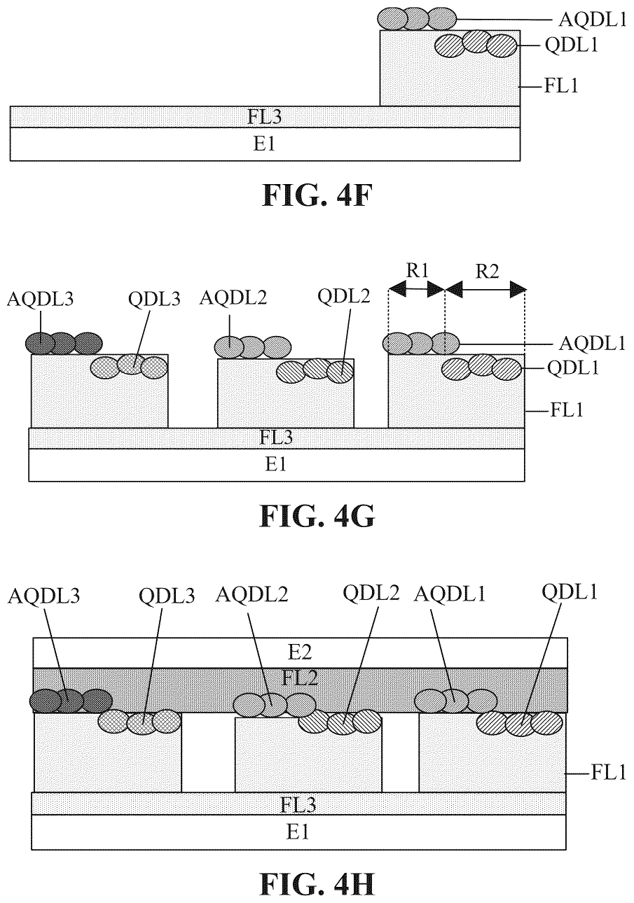

FIG. 4A to FIG. 4H illustrate a process of fabricating a light emitting device in some embodiments according to the present disclosure. Referring to FIG. 4A, a first electrode E1 is formed, and a third functional layer FL3 is formed on the first electrode E1.

Referring to FIG. 4B, a mixture layer ML is formed on a side of the third functional layer FL3 away from the first electrode E1. The mixture layer ML includes a first functional material, a first quantum dots material of a first color, and a photosensitizer. Optionally, the mixture layer ML further includes one or more solvents. In some embodiments, when the mixture layer ML is formed on a side of the third functional layer FL3 away from the first electrode E1, the first quantum dots material of the first color is dispersed in the solvent of the mixture layer ML.

Referring to FIG. 4C, the mixture layer ML is allowed to undergo a phase separation process during which the first quantum dots material of the first color segregates into a first quantum dots material layer QDML1. Upon segregation of the first quantum dots material of the first color into the first quantum dots material layer QDML1, the first functional material in the mixture layer ML forms a first functional material layer FML1. In FIG. 4C, at least a portion of the first functional material layer FML1 spaces apart the first quantum dots material layer QDML1 from the third functional layer FL3. The first quantum dots material layer QDML1 is on a side of the first functional material layer FML1 away from the first electrode E1.

In some embodiments, with respect to the first quantum dots material layer QDML1 and the first functional material layer FML1, a majority of the first quantum dots material (e.g., more than 50%, more than 60%, more than 70%, more than 80%, more than 90%, more than 95%, more than 99%, or 100%) is distributed in the first quantum dots material layer QDML1, and a minority of the first quantum dots material (e.g., less than 50%, less than 40%, less than 30%, less than 20%, less than 10%, less than 5%, less than 1%, or 0%) is distributed in the first functional material layer FML1.

In some embodiments, with respect to the first quantum dots material layer QDML1 and the first functional material layer FML1, a majority of the first functional material (e.g., more than 50%, more than 60%, more than 70%, more than 80%, more than 90%, more than 95%, more than 99%, or 100%) is distributed in the first functional material layer FML1, and a minority of the first functional material (e.g., less than 50%, less than 40%, less than 30%, less than 20%, less than 10%, less than 5%, less than 1%, or 0%) is distributed in the first quantum dots material layer QDML1.

In some embodiments, one or more first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1. In some embodiments, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots material layer QDML1 is at least partially (e.g., at least 10%, at least 20%, at least 30%, at least 40%, at least 50%, at least 60%, at least 70%, at least 80%, at least 90%, at least 95%, at least 99%, or completely) embedded in the first functional material layer FML1.

Referring to FIG. 4C, at least a portion of the first functional material layer FML1 in a first region R1 is not covered by the first quantum dots material layer QDML1 of the first color, while another portion of the first functional material layer FML1 in a second region R2 is covered by the first quantum dots material layer QDML1 of the first color. Optionally, an orthographic projection of a portion of the first functional material layer FML1 in a first region R1 on a base substrate is non-overlapping with an orthographic projection of the first quantum dots material layer QDML1 of the first color on the base substrate, and an orthographic projection of another portion of the first functional material layer FML1 in a second region R2 on the base substrate overlaps with the orthographic projection of the first quantum dots material layer QDML1 of the first color on the base substrate.

Referring to FIG. 4D, a first auxiliary quantum dots material layer AQDML1 of the first color is formed on a side of the first quantum dots material layer QDML1 and the first functional material layer FML1 away from the first electrode E1. Without the first auxiliary quantum dots material layer AQDML1 of the first color, as discussed in connection with FIG. 1A to FIG. 1G, in subsequent fabrication processes, the first functional material layer FML1 and the first quantum dots material layer QDML1 are patterned to form a first functional layer and a first quantum dots layer, and a second functional layer is formed on a side of the first functional layer and the first quantum dots layer away from the first electrode E1. Without the first auxiliary quantum dots material layer AQDML1 of the first color, at least a portion of the first functional layer in the first region R1 is in contact with the second functional layer, leading to current leakage between the first functional layer and the second functional layer, resulting in display defects.

In some embodiments, a first auxiliary quantum dots material of the first auxiliary quantum dots material layer AQDML1 of the first color extends substantially (e.g., at least 70%, at least 75%, at least 80%, at least 85%, at least 90%, at least 95%, at least 99%, or 100%) throughout the first region R1, preventing contact between the first functional layer and the second functional layer, improving display quality. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in a first region R1 on the base substrate.

In some embodiments, a combination of the first auxiliary quantum dots material of the first auxiliary quantum dots material layer AQDML1 of the first color and the first quantum dots material of the first quantum dots material layer QDML1 of the first color extends substantially (e.g., at least 70%, at least 75%, at least 80%, at least 85%, at least 90%, at least 95%, at least 99%, or 100%) throughout an entire region having the first functional material layer FML1. Optionally, an orthographic projection of a combination of the first auxiliary quantum dots material layer AQDML1 of the first color and the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of the first functional material layer FML1 on the base substrate.

In some embodiments, the first auxiliary quantum dots material of the first auxiliary quantum dots material layer AQDML1 of the first color is substantially (e.g., at least 70%, at least 75%, at least 80%, at least 85%, at least 90%, at least 95%, at least 99%, or 100%) absent in the second region R2. Optionally, the first quantum dots material of the first quantum dots material layer QDML1 of the first color extends substantially (e.g., at least 70%, at least 75%, at least 80%, at least 85%, at least 90%, at least 95%, at least 99%, or 100%) throughout the second region R2. Optionally, an orthographic projection of the first auxiliary quantum dots material layer AQDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in a first region R1 on the base substrate, and is substantially (e.g., at least 70%, at least 75%, at least 80%, at least 85%, at least 90%, at least 95%, at least 99%, or 100%) non-overlapping with an orthographic projection of a portion of the first functional material layer FML1 in a second region R2 on the base substrate. Optionally, an orthographic projection of the first quantum dots material layer QDML1 of the first color on a base substrate substantially (e.g., at least 70%, at least 75%, at least 80%, at least 85%, at least 90%, at least 95%, at least 99%, or 100%) covers an orthographic projection of a portion of the first functional material layer FML1 in the second region R2 on the base substrate.

In some embodiments, an orthographic projection of the first auxiliary quantum dots material layer AQDML1 of the first color on a base substrate is at least partially non-overlapping with an orthographic projection of the first quantum dots material layer QDML1 of the first color on the base substrate. Optionally, the orthographic projection of the first auxiliary quantum dots material layer AQDML1 of the first color on the base substrate is substantially (e.g., at least 70%, at least 75%, at least 80%, at least 85%, at least 90%, at least 95%, at least 99%, or 100%) non-overlapping with the orthographic projection of the first quantum dots material layer QDML1 of the first color on the base substrate.

Referring to FIG. 4E, a mask plate MK is used to expose a first portion of the first functional material layer FML1 by light (e.g., a UV light or a visible light). In some embodiments, in the first portion of the first functional material layer FML1 that is exposed, the photosensitizer in the first portion of the first functional material layer FML1, upon exposure to the light, initiates crosslinking reactions among the first functional material in the first portion of the first functional material layer FML1. In a second portion of the first functional material layer FML1, the photosensitizer is not exposed to light due to the mask plate MK. The first functional material in the first portion of the first functional material layer FML1 and the first functional material in the second portion of the first functional material layer FML1 have different solubilities.

Referring to FIG. 4F, the first functional material layer is developed, e.g., using a developing solution. Due to the different solubilities of the first functional material in the first portion of the first functional material layer and the first functional material in the second portion of the first functional material layer, the second portion of the first functional material layer is removed along with a portion of the first quantum dots material layer in the same region and, if any, a portion of the first auxiliary quantum dots material layer in the same region, whereas the first portion of the first functional material layer, a portion of the first quantum dots material layer in the same region, and a portion of the first auxiliary quantum dots material layer in the same region remain, thereby forming a first quantum dots layer QDL1 of the first color, a first auxiliary quantum dots layer AQDL1 of the first color, and at least a portion of a first functional layer FL1.

Quantum dots materials in the first quantum dots layer QDL1 of the first color and the first auxiliary quantum dots layer AQDL1 of the first color are quantum dots materials of the same color, e.g., the first color. In some embodiments, quantum dots materials in the first quantum dots layer QDL1 of the first color are the same as quantum dots materials in the first auxiliary quantum dots layer AQDL1 of the first color. In alternative embodiments, quantum dots materials in the first quantum dots layer QDL1 of the first color are at least partially different from quantum dots materials in the first auxiliary quantum dots layer AQDL1 of the first color.

Referring to FIG. 4G, similar processes may be reiterated to form a second quantum dots layer QDL2 of a second color, a second auxiliary quantum dots layer AQDL2 of the second color, a third quantum dots layer QDL3 of a third color, and a third auxiliary quantum dots layer AQDL3 of the third color. Referring to FIG. 4H, a second functional layer FL2 is formed on a side of the first auxiliary quantum dots layer AQDL1 of the first color, the second auxiliary quantum dots layer AQDL2 of the second color, and a third auxiliary quantum dots layer AQDL3 of the third color away from the first electrode E1. A second electrode E2 is formed on a side of the second functional layer FL2 away from the first functional layer FL1.

In some embodiments, the light emitting device includes a first subpixel of the first color, a second subpixel of the second color, and a third subpixel of the third color. In some embodiments, the first subpixel of the first color includes the first quantum dots layer QDL1 and the first auxiliary quantum dots layer AQDL1; the second subpixel of the second color includes the second quantum dots layer QDL2 and the second auxiliary quantum dots layer AQDL2; and the third subpixel of the third color includes the third quantum dots layer QDL3 and the third auxiliary quantum dots layer AQDL3.

Quantum dots materials in the second quantum dots layer QDL2 of the second color and the second auxiliary quantum dots layer AQDL2 of the second color are quantum dots materials of the same color, e.g., the second color. In some embodiments, quantum dots materials in the second quantum dots layer QDL2 of the second color are the same as quantum dots materials in the second auxiliary quantum dots layer AQDL2 of the second color. In alternative embodiments, quantum dots materials in the second quantum dots layer QDL2 of the second color are at least partially different from quantum dots materials in the second auxiliary quantum dots layer AQDL2 of the second color.

Quantum dots materials in the third quantum dots layer QDL3 of the third color and the third auxiliary quantum dots layer AQDL3 of the third color are quantum dots materials of the same color, e.g., the third color. In some embodiments, quantum dots materials in the third quantum dots layer QDL3 of the third color are the same as quantum dots materials in the third auxiliary quantum dots layer AQDL3 of the third color. In alternative embodiments, quantum dots materials in the third quantum dots layer QDL3 of the third color are at least partially different from quantum dots materials in the third auxiliary quantum dots layer AQDL3 of the third color.

In some embodiments, a first auxiliary quantum dots material of the first auxiliary quantum dots layer AQDL1 of the first color extends substantially (e.g., at least 70%, at least 75%, at least 80%, at least 85%, at least 90%, at least 95%, at least 99%, or 100%) throughout the first region R1, preventing contact between the first functional layer FL1 and the second functional layer FL2, improving display quality. Optionally, the first quantum dots material of the first quantum dots layer QDL1 of the first color extends substantially (e.g., at least 70%, at least 75%, at least 80%, at least 85%, at least 90%, at least 95%, at least 99%, or 100%) throughout the second region R2. Optionally, the first auxiliary quantum dots layer AQDL1 of the first color is substantially (e.g., at least 70%, at least 75%, at least 80%, at least 85%, at least 90%, at least 95%, at least 99%, or 100%) absent in the second region R2. Optionally, the first quantum dots layer QDL1 of the first color is substantially (e.g., at least 70%, at least 75%, at least 80%, at least 85%, at least 90%, at least 95%, at least 99%, or 100%) absent in the first region R1.

In some embodiments, a combination of the first auxiliary quantum dots material of the first auxiliary quantum dots layer AQDL1 of the first color, the first quantum dots material of the first quantum dots layer QDL1 of the first color, the second auxiliary quantum dots material of the second auxiliary quantum dots layer AQDL2 of the second color, the second quantum dots material of the second quantum dots layer QDL2 of the second color, the third auxiliary quantum dots material of the third auxiliary quantum dots layer AQDL3 of the first color, and the third quantum dots material of the third quantum dots layer QDL3 of the third color extends substantially (e.g., at least 70%, at least 75%, at least 80%, at least 85%, at least 90%, at least 95%, at least 99%, or 100%) throughout an entire region having the first functional layer FL1.

In some embodiments, the first functional layer FL1 includes a first functional material, and the second functional layer FL2 includes a second functional material.

In some embodiments, the first functional material includes a first carrier transport material, and the second functional material includes a second carrier transport material different from the first carrier transport material. In some embodiments, the first carrier transport material includes a hole transport material, and the second carrier transport material includes an electron transport material. Optionally, the first carrier transport material includes a hole transport material, the second carrier transport material includes an electron transport material, and the third functional layer FL3 is a hole injection layer. Optionally, the first carrier transport material includes a hole transport material, the second carrier transport material includes an electron transport material, the third functional layer FL3 is a hole injection layer, the first electrode E1 is an anode, and the second electrode E2 is a cathode. Optionally, light emitted from the light emitting device along a direction from the first electrode E1 to the second electrode E2.

In alternative embodiments, the first carrier transport material includes an electron transport material, and the second carrier transport material includes a hole transport material. Optionally, the first carrier transport material includes an electron transport material, the second carrier transport material includes a hole transport material, and the third functional layer FL3 is an electron injection layer. Optionally, the first carrier transport material includes an electron transport material, the second carrier transport material includes a hole transport material, the third functional layer FL3 is an electron injection layer, the first electrode E1 is a cathode, and the second electrode E2 is an anode. Optionally, light emitted from the light emitting device along a direction from the second electrode E2 to the first electrode E1.

Referring to FIG. 4H, the light emitting device in some embodiments includes a first electrode E1; a second electrode E2; and a first functional layer FL1, a first quantum dots layer QDL1 of the first color, a first auxiliary quantum dots layer AQDL1, and a second functional layer FL2 between the first electrode E1 and the second electrode E2. Optionally, the first auxiliary quantum dots layer AQDL1 of the first color is in contact with the first functional layer FL1 and in contact with the second functional layer FL2. Optionally, the first auxiliary quantum dots layer AQDL1 of the first color is in contact with the first quantum dots layer QDL1 of the first color.

In some embodiments, one or more first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the first quantum dots of the first quantum dots layer QDL1 of the first color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, the first auxiliary quantum dots layer AQDL1 is on a side of the first quantum dots layer QDL1 and the first functional layer FL1 away from the first electrode E1.

In some embodiments, with respect to the first quantum dots layer QDL1 of the first color and the first functional layer FL1, a majority of the first quantum dots material (e.g., more than 50%, more than 60%, more than 70%, more than 80%, more than 90%, more than 95%, more than 99%, or 100%) is distributed in the first quantum dots layer QDL1 of the first color, and a minority of the first quantum dots material (e.g., less than 50%, less than 40%, less than 30%, less than 20%, less than 10%, less than 5%, less than 1%, or 0%) is distributed in the first functional layer FL1.

In some embodiments, with respect to the first quantum dots layer QDL1 of the first color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the first quantum dots layer QDL1 of the first color.

In some embodiments, the first functional material in the first functional layer FL1 is at least partially (e.g., at least 10%, at least 20%, at least 30%, at least 40%, at least 50%, at least 60%, at least 70%, at least 80%, at least 90%, at least 95%, at least 99%, or 100%) cross-linked.

In some embodiments, an orthographic projection of the first auxiliary quantum dots layer AQDL1 of the first color on a base substrate is at least partially non-overlapping with an orthographic projection of the first quantum dots layer QDL1 of the first color on the base substrate. Optionally, the orthographic projection of the first auxiliary quantum dots layer AQDL1 of the first color on the base substrate is substantially (e.g., at least 70%, at least 75%, at least 80%, at least 85%, at least 90%, at least 95%, at least 99%, or 100%) non-overlapping with the orthographic projection of the first quantum dots layer QDL1 of the first color on the base substrate.

In some embodiments, the light emitting device further includes a second quantum dots layer QDL2 of the second color and a second auxiliary quantum dots layer AQDL2 between the first electrode E1 and the second electrode E2. Optionally, the second auxiliary quantum dots layer AQDL2 of the second color is in contact with the first functional layer FL1 and in contact with the second functional layer FL2. Optionally, the second auxiliary quantum dots layer AQDL2 of the second color is in contact with the second quantum dots layer QDL2 of the second color.

In some embodiments, one or more second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the second quantum dots of the second quantum dots layer QDL2 of the second color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the second quantum dots layer QDL2 of the second color and the first functional layer FL1, a majority of the second quantum dots material (e.g., more than 50%, more than 60%, more than 70%, more than 80%, more than 90%, more than 95%, more than 99%, or 100%) is distributed in the second quantum dots layer QDL2 of the second color, and a minority of the second quantum dots material (e.g., less than 50%, less than 40%, less than 30%, less than 20%, less than 10%, less than 5%, less than 1%, or 0%) is distributed in the first functional layer FL1.

In some embodiments, with respect to the second quantum dots layer QDL2 of the second color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the second quantum dots layer QDL2 of the second color.

In some embodiments, an orthographic projection of the second auxiliary quantum dots layer AQDL2 of the second color on a base substrate is at least partially non-overlapping with an orthographic projection of the second quantum dots layer QDL2 of the second color on the base substrate. Optionally, the orthographic projection of the second auxiliary quantum dots layer AQDL2 of the second color on the base substrate is substantially (e.g., at least 70%, at least 75%, at least 80%, at least 85%, at least 90%, at least 95%, at least 99%, or 100%) non-overlapping with the orthographic projection of the second quantum dots layer QDL2 of the second color on the base substrate.

In some embodiments, the light emitting device further includes a third quantum dots layer QDL3 of the third color and a third auxiliary quantum dots layer AQDL3 between the first electrode E1 and the second electrode E2. Optionally, the third auxiliary quantum dots layer AQDL3 of the third color is in contact with the first functional layer FL1 and in contact with the second functional layer FL2. Optionally, the third auxiliary quantum dots layer AQDL3 of the third color is in contact with third quantum dots layer QDL3 of the third color.

In some embodiments, one or more third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1. Optionally, at least 10% (e.g., at least 20%, at least 30%, at least 40%, at least 50%, at least 60%, at least 70%, at least 80%, at least 90%, at least 95%, at least 99%, or 100%) of the third quantum dots of the third quantum dots layer QDL3 of the third color is at least partially (e.g., at least 10%, at least 20%, at least 30%, at least 40%, at least 50%, at least 60%, at least 70%, at least 80%, at least 90%, at least 95%, at least 99%, or completely) embedded in the first functional layer FL1.

In some embodiments, with respect to the third quantum dots layer QDL3 of the third color and the first functional layer FL1, a majority of the third quantum dots material (e.g., more than 50%, more than 60%, more than 70%, more than 80%, more than 90%, more than 95%, more than 99%, or 100%) is distributed in the third quantum dots layer QDL3 of the third color, and a minority of the third quantum dots material (e.g., less than 50%, less than 40%, less than 30%, less than 20%, less than 10%, less than 5%, less than 1%, or 0%) is distributed in the first functional layer FL1.

In some embodiments, with respect to the third quantum dots layer QDL3 of the third color and the first functional layer FL1, a majority of the first functional material (e.g., more than 50%, more than 60%, more than 70%, more than 80%, more than 90%, more than 95%, more than 99%, or 100%) is distributed in the first functional layer FL1, and a minority of the first functional material (e.g., less than 50%, less than 40%, less than 30%, less than 20%, less than 10%, less than 5%, less than 1%, or 0%) is distributed in the third quantum dots layer QDL3 of the third color.

In some embodiments, an orthographic projection of the third auxiliary quantum dots layer AQDL3 of the third color on a base substrate is at least partially non-overlapping with an orthographic projection of the third quantum dots layer QDL3 of the third color on the base substrate. Optionally, the orthographic projection of the third auxiliary quantum dots layer AQDL3 of the third color on the base substrate is substantially (e.g., at least 70%, at least 75%, at least 80%, at least 85%, at least 90%, at least 95%, at least 99%, or 100%) non-overlapping with the orthographic projection of the third quantum dots layer QDL3 of the third color on the base substrate.

In some embodiments, the first color, the second color, and the third color are different from each other. Optionally, the first color, the second color, and the third color are three different colors selected from a red color, a green color, and a blue color.

The inventors of the present disclosure discover that, referring to FIG. 4A to FIG. 4H, the presence of the auxiliary quantum dots layers (including the first auxiliary quantum dots layer AQDL1, the second auxiliary quantum dots layer AQDL2, and the third auxiliary quantum dots layer AQDL3) prevents the contact between the first functional layer FL1 and the second functional layer FL2, and the current leakage between the first functional layer FL1 and the second functional layer FL2, significantly improving display quality.

In some embodiments, quantum dots materials include an inorganic portion and a ligand. For example, the quantum dots materials in some embodiments include a shell, a core, and a ligand. The core and the shell, as used herein, may be referred to as QD core-shell, or QD core-shell structure, or core-shell structure. The core-shell structure may be made of materials such as CdS, CdSe, CdTe, ZnSe, InP, PbS, CsPbCl3, CsPbBr3, CsPhI3, CsPbClxBr3−x, CsPbBrxI3−x, CdS/ZnS, CdSe/ZnS, ZnSe, InP/ZnS, PbS/ZnS, CsPbCl3/ZnS, CsPbBr3/ZnS, CsPhI3/ZnS, CsPbClxBr3−x/ZnS, CsPhBrxI3−x/ZnS, and combination(s) thereof, where x is a positive integer and x<3.

In some embodiments, quantum dots materials in the first quantum dots layer QDL1 of the first color include a first ligand, and quantum dots materials in the first auxiliary quantum dots layer AQDL1 of the first color include a first auxiliary ligand. In some embodiments, ligands in the first quantum dots layer QDL1 of the first color have a same polarity. In some embodiments, ligands in the first auxiliary quantum dots layer AQDL1 of the first color have a same polarity. In some embodiments, the first ligand and the first auxiliary ligand have different polarities.

In some embodiments, the first ligand includes a first binding group that binds to an inorganic portion of quantum dots materials in the first quantum dots layer QDL1 of the first color and a first tail connected to the first binding group; and the first auxiliary ligand includes a first auxiliary binding group that binds to an inorganic portion of quantum dots materials in the first auxiliary quantum dots layer AQDL1 and a first auxiliary tail connected to the first auxiliary binding group.

In some embodiments, the first tail has a first polarity, and the first auxiliary tail has a second polarity. Polarity of a material may be measured by various appropriate methods. In one example, polarity is measured by dipole moment. In another example, a dipole moment between 0 Debye and 1 Debye is considered as non-polar, and a dipole moment equal to or greater than 1 Debye is considered as polar.

In some embodiments, the first tail is a non-polar group, the first auxiliary tail is a polar group. In one example, the first ligand is oleic acid. In another example, the first auxiliary ligand is mono-2-(methacryloyloxy) ethyl succinate. In another example, the first auxiliary ligand is a ligand having a fluorinated group or a cyanide group.

In alternative embodiments, the first tail is a polar group, and the first auxiliary tail is a non-polar group. In one example, the first ligand is mono-2-(methacryloyloxy) ethyl succinate. In another example, the first auxiliary ligand is oleic acid.

In alternative embodiments, the first tail is a polar group, and the first auxiliary tail is a non-polar group. In one example, the first ligand is a ligand having a fluorinated group or a cyanide group. In another example, the first auxiliary ligand is oleic acid.

In alternative embodiments, the first tail is a polar group, and the first auxiliary tail is a polar group. In one example, the first ligand is mono-2-(methacryloyloxy) ethyl succinate. In another example, the first auxiliary ligand is a ligand having a fluorinated group or a cyanide group.

In alternative embodiments, the first tail is a polar group, and the first auxiliary tail is a polar group. In one example, the first ligand is a ligand having a fluorinated group or a cyanide group. In another example, the first auxiliary ligand is mono-2-(methacryloyloxy) ethyl succinate.

In some embodiments, the mixture layer ML for forming the first quantum dots layer QDL1 includes a first solvent for dissolving the first quantum dots material, and a second solvent for dissolving the first functional material. In some embodiments, the first solvent and the second solvent have different polarities. In some embodiments, a difference between the first polarity of the first tail of the first ligand of quantum dots materials in the first quantum dots material and a polarity of the first solvent is smaller than a difference between the first polarity of the first tail of the first ligand of quantum dots materials in the first quantum dots material and a polarity of the second solvent.

In some embodiments, the first tail is a non-polar group, the first solvent is a non-polar solvent, and the second solvent is a polar solvent.

In alternative embodiments, the first tail is a polar group, the first solvent is a polar solvent, and the second solvent is a non-polar solvent.

In some embodiments, the first solvent has a first density, the second solvent has a second density. Optionally, the first density is different from the second density. In one example, the first density is smaller than the second density.

In one example, the mixture layer ML includes the first functional material, chlorobenzene, a quantum dots material having oleic acid as ligand, octane, mono-2-(methacryloyloxy) ethyl succinate, propylene glycol methyl ether acetate, and methanol. Subsequent to phase separation and drying, the first functional material layer FML1 includes the first functional material; and the first quantum dots material layer QDML1 includes the first quantum dots material having mono-2-(methacryloyloxy) ethyl succinate as the ligand.

In another example, the first auxiliary quantum dots material layer AQDML1 is formed by applying a solution including the first auxiliary quantum dots material having oleic acid as the ligand, and octane as the solvent.

In some embodiments, quantum dots materials in the second quantum dots layer QDL2 of the second color include a second ligand, and quantum dots materials in the second auxiliary quantum dots layer AQDL2 of the second color include a second auxiliary ligand. In some embodiments, ligands in the second quantum dots layer QDL2 of the second color have a same polarity. In some embodiments, ligands in the second auxiliary quantum dots layer AQDL2 of the second color have a same polarity. In some embodiments, the second ligand and the second auxiliary ligand have different polarities.

In some embodiments, the second ligand includes a second binding group that binds to an inorganic portion of quantum dots materials in the second quantum dots layer QDL2 of the second color and a second tail connected to the second binding group; and the second auxiliary ligand includes a second auxiliary binding group that binds to an inorganic portion of quantum dots materials in the second auxiliary quantum dots layer AQDL2 and a second auxiliary tail connected to the second auxiliary binding group.

In some embodiments, the second tail has a third polarity, and the second auxiliary tail has a fourth polarity.

In some embodiments, the second tail is a non-polar group, and the second auxiliary tail is a polar group. In one example, the second ligand is oleic acid. In another example, the second auxiliary ligand is mono-2-(methacryloyloxy) ethyl succinate. In another example, the second auxiliary ligand is a ligand having a fluorinated group or a cyanide group.

In alternative embodiments, the second tail is a polar group, and the second auxiliary tail is a non-polar group. In one example, the second ligand is mono-2-(methacryloyloxy) ethyl succinate. In another example, the second auxiliary ligand is oleic acid.

In alternative embodiments, the second tail is a polar group, and the second auxiliary tail is a non-polar group. In one example, the second ligand is a ligand having a fluorinated group or a cyanide group. In another example, the second auxiliary ligand is oleic acid.

In alternative embodiments, the second tail is a polar group, and the second auxiliary tail is a polar group. In one example, the second ligand is mono-2-(methacryloyloxy) ethyl succinate. In another example, the second auxiliary ligand is a ligand having a fluorinated group or a cyanide group.

In alternative embodiments, the second tail is a polar group, and the second auxiliary tail is a polar group. In one example, the second ligand is a ligand having a fluorinated group or a cyanide group. In another example, the second auxiliary ligand is mono-2-(methacryloyloxy) ethyl succinate.

In some embodiments, the mixture layer ML for forming the second quantum dots layer QDL2 includes a third solvent for dissolving the second quantum dots material, and a fourth solvent for dissolving the first functional material. In some embodiments, the third solvent and the fourth solvent have different polarities. In some embodiments, a difference between the third polarity of the second tail of the second ligand of quantum dots materials in the second quantum dots material and a polarity of the third solvent is smaller than a difference between the third polarity of the second tail of the second ligand of quantum dots materials in the second quantum dots material and a polarity of the fourth solvent.

In some embodiments, the second tail is a non-polar group, the third solvent is a non-polar solvent, and the fourth solvent is a polar solvent.

In alternative embodiments, the second tail is a polar group, the third solvent is a polar solvent, and the fourth solvent is a non-polar solvent.

In some embodiments, the third solvent has a third density, the fourth solvent has a fourth density. Optionally, the third density is different from the fourth density. In one example, the third density is smaller than the fourth density.

In one example, the mixture layer ML includes the first functional material, chlorobenzene, a quantum dots material having oleic acid as ligand, octane, mono-2-(methacryloyloxy) ethyl succinate, propylene glycol methyl ether acetate, and methanol. Subsequent to phase separation and drying, the first functional material layer FML1 includes the first functional material; and the second quantum dots material layer includes the second quantum dots material having mono-2-(methacryloyloxy) ethyl succinate as the ligand.

In another example, the second auxiliary quantum dots material layer is formed by applying a solution including the second auxiliary quantum dots material having oleic acid as the ligand, and octane as the solvent.

In some embodiments, quantum dots materials in the third quantum dots layer QDL3 of the third color include a third ligand, and quantum dots materials in the third auxiliary quantum dots layer AQDL3 of the third color include a third auxiliary ligand. In some embodiments, ligands in the third quantum dots layer QDL3 of the third color have a same polarity. In some embodiments, ligands in the third auxiliary quantum dots layer AQDL3 of the third color have a same polarity. In some embodiments, the third ligand and the third auxiliary ligand have different polarities.

In some embodiments, the third ligand includes a third binding group that binds to an inorganic portion of quantum dots materials in the third quantum dots layer QDL3 of the third color and a third tail connected to the third binding group; and the third auxiliary ligand includes a third auxiliary binding group that binds to an inorganic portion of quantum dots materials in the third auxiliary quantum dots layer AQDL3 and a third auxiliary tail connected to the fifth auxiliary binding group.

In some embodiments, the third tail has a fifth polarity, and the third auxiliary tail has a sixth polarity.

In some embodiments, the third tail is a non-polar group, the third auxiliary tail is a polar group. In one example, the third ligand is oleic acid. In another example, the third auxiliary ligand is mono-2-(methacryloyloxy) ethyl succinate. In another example, the third auxiliary ligand is a ligand having a fluorinated group or a cyanide group.

In alternative embodiments, the third tail is a polar group, and the third auxiliary tail is a non-polar group. In one example, the third ligand is mono-2-(methacryloyloxy) ethyl succinate. In another example, the third auxiliary ligand is oleic acid.

In alternative embodiments, the third tail is a polar group, and the third auxiliary tail is a non-polar group. In one example, the third ligand is a ligand having a fluorinated group or a cyanide group. In another example, the third auxiliary ligand is oleic acid.

In alternative embodiments, the third tail is a polar group, and the third auxiliary tail is a polar group. In one example, the third ligand is mono-2-(methacryloyloxy) ethyl succinate. In another example, the third auxiliary ligand is a ligand having a fluorinated group or a cyanide group.

In alternative embodiments, the third tail is a polar group, and the third auxiliary tail is a polar group. In one example, the third ligand is a ligand having a fluorinated group or a cyanide group. In another example, the third auxiliary ligand is mono-2-(methacryloyloxy) ethyl succinate.

In some embodiments, the mixture layer ML for forming the third quantum dots layer QDL3 includes a fifth solvent for dissolving the third quantum dots material, and a sixth solvent for dissolving the first functional material. In some embodiments, the fifth solvent and the sixth solvent have different polarities. In some embodiments, a difference between the seventh polarity of the third tail of the third ligand of quantum dots materials in the third quantum dots material and a polarity of the fifth solvent is smaller than a difference between the seventh polarity of the third tail of the third ligand of quantum dots materials in the third quantum dots material and a polarity of the sixth solvent.

In some embodiments, the third tail is a non-polar group, the fifth solvent is a non-polar solvent, and the sixth solvent is a polar solvent.

In alternative embodiments, the third tail is a polar group, the fifth solvent is a polar solvent, and the sixth solvent is a non-polar solvent.

In some embodiments, the fifth solvent has a fifth density, the sixth solvent has a sixth density. Optionally, the fifth density is different from the sixth density. In one example, the fifth density is smaller than the sixth density.

In one example, the mixture layer ML includes the first functional material, chlorobenzene, a quantum dots material having oleic acid as ligand, octane, mono-2-(methacryloyloxy) ethyl succinate, propylene glycol methyl ether acetate, and methanol. Subsequent to phase separation and drying, the first functional material layer FML1 includes the first functional material; and the third quantum dots material layer includes the third quantum dots material having mono-2-(methacryloyloxy) ethyl succinate as the ligand.

In another example, the third auxiliary quantum dots material layer is formed by applying a solution including the third auxiliary quantum dots material having oleic acid as the ligand, and octane as the solvent.

The inventors of the present disclosure discover that, in quantum dots display panels having red, green, and blue subpixels, multiple electrons can occupy the same energy state or band within the quantum dots material of a red color, multiple electrons can occupy the same energy state or band within the quantum dots material of a green color, and multiple holes can occupy the same energy state or band within the quantum dots material of a blue color. When a hole transport layer of a same hole transport material is used for red, green, and blue subpixels, the inventors of the present disclosure discover that the light emitting device according to the present disclosure can ensure that the hole-transport is balanced between the red/green subpixels and the blue subpixels. To achieve balance, the inventors of the present disclosure discover that it is necessary to make the highest occupied molecular orbital (HOMO) energy level of the ligands associated with the blue subpixels deeper, e.g., raising the HOMO energy level in the quantum dots material in the blue subpixels. The HOMO energy level is the highest energy level in a molecule where electrons are present. It represents the energy level of the highest occupied electron. By making the HOMO deeper, it becomes more challenging for holes to be injected into the blue region.

The inventors of the present disclosure discover that ligands having fluorinated group or cyanide group play a role in deepening the HOMO of the ligands and increasing resistance. The inventors of the present disclosure discover that, to achieve the desired balance, the quantum dots material in the red/green subpixels may have less content of fluorinated group than the quantum dots material in the blue subpixels.

In some embodiments, referring to FIG. 2A to FIG. 2H, FIG. 3A to FIG. 3H, and FIG. 4A to FIG. 4H, the light emitting device includes a first subpixel of the first color, a second subpixel of the second color, and a third subpixel of the third color. In some embodiments, the first subpixel of the first color includes the first quantum dots layer QDL1 and the first auxiliary quantum dots layer AQDL1; the second subpixel of the second color includes the second quantum dots layer QDL2 and the second auxiliary quantum dots layer AQDL2; and the third subpixel of the third color includes the third quantum dots layer QDL3 and the third auxiliary quantum dots layer AQDL3. In one example, the first color is a red color, the second color is a green color, and the third color is a blue color.

In some embodiments, quantum dots materials in the first quantum dots layer QDL1 of the first color include a ligand having a fluorinated group, quantum dots materials in the second quantum dots layer QDL2 of the second color include a ligand having a fluorinated group; and quantum dots materials in the third quantum dots layer QDL3 of the third color include a ligand having a fluorinated group. In some embodiments, a number of fluorine atoms in the ligands of the third quantum dots layer QDL3 of the third color is greater than a number of fluorine atoms in the ligands of the first quantum dots layer QDL1 of the first color, and is greater than a number of fluorine atoms in the ligands of the second quantum dots layer QDL2 of the second color. Optionally, the first functional layer includes a hole transport material. Optionally, the second functional layer includes an electron transport material. In one example, the first color is a red color, the second color is a green color, and the third color is a blue color.

In some embodiments, quantum dots materials in the first auxiliary quantum dots layer AQDL1 of the first color include a ligand having a fluorinated group and/or a cyanide group, quantum dots materials in the second auxiliary quantum dots layer AQDL2 of the second color include a ligand having a fluorinated group and/or a cyanide group; and quantum dots materials in the third auxiliary quantum dots layer AQDL3 of the third color include a ligand having a fluorinated group and/or a cyanide group. In some embodiments, a thickness of the third auxiliary quantum dots layer AQDL3 of the third color is greater than a thickness of the first auxiliary quantum dots layer AQDL1 of the first color, and is greater than a thickness of the second auxiliary quantum dots layer AQDL2 of the second color. Optionally, the first functional layer includes an electron transport material. Optionally, the second functional layer includes a hole transport material. In one example, the first color is a red color, the second color is a green color, and the third color is a blue color.

In some embodiments, quantum dots materials in the first auxiliary quantum dots layer AQDL1 of the first color include a ligand having a fluorinated group and/or a cyanide group, quantum dots materials in the second auxiliary quantum dots layer AQDL2 of the second color include a ligand having a fluorinated group and/or a cyanide group; and quantum dots materials in the third auxiliary quantum dots layer AQDL3 of the third color include a ligand having a fluorinated group and/or a cyanide group. In some embodiments, a number of the fluorinated group and/or a cyanide group in the third auxiliary quantum dots layer AQDL3 of the third color is greater than a number of the fluorinated group and/or a cyanide group in the first auxiliary quantum dots layer AQDL1 of the first color, and is greater than a number of the fluorinated group and/or a cyanide group in the second auxiliary quantum dots layer AQDL2 of the second color. Optionally, the first functional layer includes an electron transport material. Optionally, the second functional layer includes a hole transport material. In one example, the first color is a red color, the second color is a green color, and the third color is a blue color.

Particularly for top-emitting devices, microcavity lengths for subpixels are adjusted to optimize the microcavity effect. In some embodiments, a microcavity length for the first subpixel of the first color is greater than a microcavity length for the second subpixel of the second color, and the microcavity length for the second subpixel of the second color is greater than a microcavity length for the third subpixel of the third color. In some embodiments, the microcavity lengths for subpixels are adjusted by adjusting thicknesses of respective portions of the first functional layer FL1 in different subpixels, respectively. In some embodiments, a thickness of a first portion of the first functional layer FL1 in the first subpixel of the first color is greater than a thickness of a second portion of the first functional layer FL1 in the second subpixel of the second color, and the thickness of the second portion of the first functional layer FL1 in the second subpixel of the second color is greater than a thickness of a third portion of the first functional layer FL1 in the third subpixel of the third color.

To achieve a greater thickness of the portion of the first functional layer FL1, a corresponding mixture layer with a greater thickness is required. As the corresponding mixture layer becomes thicker, it becomes more difficult for the corresponding mixture layer to undergo a complete phase separation. The inventors of the present disclosure discover that as a number of ligands in the quantum dots material in the corresponding mixture layer increases, it becomes easier for the corresponding mixture layer to undergo a complete phase separation.

In some embodiments, a particle size of the first quantum dots material of the first color in the corresponding mixture layer for forming the first quantum dots layer QDL1 of the first color in the first subpixel of the first color is greater than a particle size of the second quantum dots material of the second color in the corresponding mixture layer for forming the second quantum dots layer QDL2 of the second color in the second subpixel of the second color; and the particle size of the second quantum dots material of the second color in the corresponding mixture layer for forming the second quantum dots layer QDL2 of the second color in the second subpixel of the second color is greater than a particle size of the third quantum dots material of the third color in the corresponding mixture layer for forming the third quantum dots layer QDL3 of the third color in the third subpixel of the third color. In one example, the first color is a red color, the second color is a green color, and the third color is a blue color.

In some embodiments, a specific surface area of the third quantum dots material of the third color in the corresponding mixture layer for forming the third quantum dots layer QDL3 of the third color in the third subpixel of the third color is greater than a specific surface area of the second quantum dots material of the second color in the corresponding mixture layer for forming the second quantum dots layer QDL2 of the second color in the second subpixel of the second color; and the specific surface area of the second quantum dots material of the second color in the corresponding mixture layer for forming the second quantum dots layer QDL2 of the second color in the second subpixel of the second color is greater than a specific surface area of the first quantum dots material of the first color in the corresponding mixture layer for forming the first quantum dots layer QDL1 of the first color in the first subpixel of the first color. In one example, the first color is a red color, the second color is a green color, and the third color is a blue color.

In some embodiments, a number of ligands in the third quantum dots material of the third color in the corresponding mixture layer for forming the third quantum dots layer QDL3 of the third color in the third subpixel of the third color is greater than a number of ligands in the second quantum dots material of the second color in the corresponding mixture layer for forming the second quantum dots layer QDL2 of the second color in the second subpixel of the second color; and the number of ligands in the second quantum dots material of the second color in the corresponding mixture layer for forming the second quantum dots layer QDL2 of the second color in the second subpixel of the second color is greater than a number of ligands in the first quantum dots material of the first color in the corresponding mixture layer for forming the first quantum dots layer QDL1 of the first color in the first subpixel of the first color. In one example, the first color is a red color, the second color is a green color, and the third color is a blue color.

Based on the particle sizes, the specific surface areas, and the number of ligands for respective quantum dots materials, in some embodiments, a degree of phase separation in the corresponding mixture layer for forming the third quantum dots layer QDL3 of the third color in the third subpixel of the third color is greater than a degree of phase separation in the corresponding mixture layer for forming the second quantum dots layer QDL2 of the second color in the second subpixel of the second color; and the degree of phase separation in the corresponding mixture layer for forming the second quantum dots layer QDL2 of the second color in the second subpixel of the second color is greater than a degree of phase separation in the corresponding mixture layer for forming the first quantum dots layer QDL1 of the first color in the first subpixel of the first color. In one example, the first color is a red color, the second color is a green color, and the third color is a blue color.

Due to the different degrees of phase separation in respective mixture layers, in some embodiments, a spacing between quantum dots particles in the first quantum dots layer QDL1 of the first color in the first subpixel of the first color is greater than a spacing between quantum dots particles in the second quantum dots layer QDL2 of the second color in the second subpixel of the second color; and the spacing between quantum dots particles in the second quantum dots layer QDL2 of the second color in the second subpixel of the second color is greater than a spacing between quantum dots particles in the third quantum dots layer QDL3 of the third color in the third subpixel of the third color. In one example, the first color is a red color, the second color is a green color, and the third color is a blue color.

In some embodiments, to compensate the different particle spacing in respective quantum dots layers, a thickness of the first auxiliary quantum dots layer AQDL1 of the first color is greater than a thickness of the second auxiliary quantum dots layer AQDL2 of the second color; and the thickness of the second auxiliary quantum dots layer AQDL2 of the second color is greater than a thickness of the third auxiliary quantum dots layer AQDL3 of the third color. In one example, the first color is a red color, the second color is a green color, and the third color is a blue color.

In some embodiments, quantum dots materials in the first quantum dots layer QDL1 of the first color include a ligand having a fluorinated group, quantum dots materials in the second quantum dots layer QDL2 of the second color include a ligand having a fluorinated group; and quantum dots materials in the third quantum dots layer QDL3 of the third color include a ligand having a fluorinated group. In some embodiments, a number of fluorine atoms in the ligands of the third quantum dots layer QDL3 of the third color is greater than a number of fluorine atoms in the ligands of the first quantum dots layer QDL1 of the first color, and is greater than a number of fluorine atoms in the ligands of the second quantum dots layer QDL2 of the second color.

In some embodiments, quantum dots materials in the first auxiliary quantum dots layer AQDL1 of the first color include a ligand having a fluorinated group and/or a cyanide group, quantum dots materials in the second auxiliary quantum dots layer AQDL2 of the second color include a ligand having a fluorinated group and/or a cyanide group; and quantum dots materials in the third auxiliary quantum dots layer AQDL3 of the third color include a ligand having a fluorinated group and/or a cyanide group. In some embodiments, a thickness of the first auxiliary quantum dots layer AQDL1 of the first color is greater than a thickness of the second auxiliary quantum dots layer AQDL2 of the second color; and the thickness of the second auxiliary quantum dots layer AQDL2 of the second color is greater than a thickness of the third auxiliary quantum dots layer AQDL3 of the third color. Ligands for the auxiliary quantum dots layers may be polar or non-polar. In one example, the first color is a red color, the second color is a green color, and the third color is a blue color.

In another aspect, the present disclosure provides a display panel comprising the light emitting device described herein or fabricated by a method described herein, and one or more transistors configured to control light emission of the light emitting device.

In another aspect, the present disclosure provides a display apparatus comprising the display panel described herein, and one or more integrated circuits connected to the display panel. Examples of appropriate display apparatuses include, but are not limited to, an electronic paper, a mobile phone, a tablet computer, a television, a monitor, a notebook computer, a digital album, a GPS, etc.

In another aspect, the present disclosure provides a method of fabricating a light emitting device. In some embodiments, the method includes forming a first electrode; forming a second electrode; and forming a first functional layer, a first quantum dots layer of the first color, a first auxiliary quantum dots layer, and a second functional layer between the first electrode and the second electrode. Optionally, one or more first quantum dots of the first quantum dots layer of the first color is at least partially embedded in the first functional layer. Optionally, the first functional material in the first functional layer is at least partially cross-linked.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A light emitting device, comprising:
a first electrode;
a second electrode; and
a first functional layer, a first quantum dots layer of a first color, a first auxiliary quantum dots layer, and a second functional layer between the first electrode and the second electrode;
wherein one or more first quantum dots of the first quantum dots layer of the first color is at least partially embedded in the first functional layer; and
a first functional material in the first functional layer is at least partially cross-linked.

2. The light emitting device of claim 1, wherein the first auxiliary quantum dots layer is in contact with the first functional layer and in contact with the second functional layer; and
the first auxiliary quantum dots layer is in contact with the first quantum dots layer of the first color.

3. The light emitting device of claim 1, wherein, with respect to the first quantum dots layer of the first color and the first functional layer, a majority of a first quantum dots material is distributed in the first quantum dots layer of the first color, and a minority of the first quantum dots material is distributed in the first functional layer; and
with respect to the first quantum dots layer of the first color and the first functional layer, a majority of the first functional material is distributed in the first functional layer, and a minority of the first functional material is distributed in the first quantum dots layer of the first color.

4. The light emitting device of claim 1, wherein quantum dots materials in the first quantum dots layer of the first color comprise a first ligand;
quantum dots materials in the first auxiliary quantum dots layer include a first auxiliary ligand and a second auxiliary ligand;
ligands in the first quantum dots layer of the first color have a same polarity; and
the first auxiliary ligand and the second auxiliary ligand have different polarities.

5. The light emitting device of claim 4, wherein the first ligand comprises a first binding group that binds to an inorganic portion of quantum dots materials in the first quantum dots layer of the first color and a first tail connected to the first binding group;
the first auxiliary ligand includes a first auxiliary binding group that binds to an inorganic portion of quantum dots materials in the first auxiliary quantum dots layer and a first auxiliary tail connected to the first auxiliary binding group; and
the second auxiliary ligand includes a second auxiliary binding group that binds to an inorganic portion of quantum dots materials in the first auxiliary quantum dots layer and a second auxiliary tail connected to the second auxiliary binding group;
wherein the first tail has a first polarity;
the first auxiliary tail has a second polarity;
the second auxiliary tail has a third polarity; and
a difference between the first polarity and the second polarity is smaller than a difference between the first polarity and the third polarity.

6. The light emitting device of claim 1, wherein the first auxiliary quantum dots layer is on a side of the first quantum dots layer away from the first functional layer.

7. The light emitting device of claim 6, wherein the second functional layer is on a side of the first auxiliary quantum dots layer away from the first quantum dots layer.

8. The light emitting device of claim 6, further comprising a third functional layer on a side of the first functional layer away from the first quantum dots layer and the first auxiliary quantum dots layer;
wherein the first functional layer is in contact with the third functional layer.

9. The light emitting device of claim 1, wherein the first quantum dots layer is on a side of the first auxiliary quantum dots layer and the second functional layer away from the first electrode;
the first auxiliary quantum dots layer is on a side of the first quantum dots layer away from the first functional layer;
the second functional layer is on a side of the first auxiliary quantum dots layer and the first quantum dots layer away from the first functional layer; and
the first auxiliary quantum dots layer are in contact with the second functional layer.

10. The light emitting device of claim 1, wherein the first quantum dots layer has a non-uniform thickness; and
a combination of the first quantum dots layer and the first auxiliary quantum dots layer has a non-uniform thickness.

11. The light emitting device of claim 1, wherein an orthographic projection of the first auxiliary quantum dots layer on a base substrate substantially covers an orthographic projection of the first quantum dots layer on the base substrate.

12. The light emitting device of claim 1, wherein an orthographic projection of the first auxiliary quantum dots layer on a base substrate is substantially non-overlapping with an orthographic projection of the first quantum dots layer on the base substrate.

13. The light emitting device of claim 1, wherein quantum dots materials in the first quantum dots layer of the first color comprise a first ligand;
quantum dots materials in the first auxiliary quantum dots layer include a first auxiliary ligand;
ligands in the first quantum dots layer of the first color have a same polarity;
ligands in the first auxiliary quantum dots layer have a same polarity; and
the first ligand and the first auxiliary ligand have different polarities.

14. The light emitting device of claim 13, wherein the first ligand comprises a first binding group that binds to an inorganic portion of quantum dots materials in the first quantum dots layer of the first color and a first tail connected to the first binding group; and
the first auxiliary ligand includes a first auxiliary binding group that binds to an inorganic portion of quantum dots materials in the first auxiliary quantum dots layer and a first auxiliary tail connected to the first auxiliary binding group;
wherein the first tail has a first polarity;
the first auxiliary tail has a second polarity; and
the first polarity is different from the second polarity.

15. The light emitting device of claim 1, wherein quantum dots materials in the first quantum dots layer of the first color and the first auxiliary quantum dots layer are quantum dots materials of the same color.

16. The light emitting device of claim 1, comprising a first subpixel of the first color, a second subpixel of a second color, and a third subpixel of a third color;
wherein the first subpixel of the first color comprises the first quantum dots layer and the first auxiliary quantum dots layer;
the second subpixel of the second color comprises a second quantum dots layer and a second auxiliary quantum dots layer;
the third subpixel of the third color comprises a third quantum dots layer and a third auxiliary quantum dots layer;
quantum dots materials in the first quantum dots layer of the first color comprise a ligand having a fluorinated group;
quantum dots materials in the second quantum dots layer of the second color comprise a ligand having a fluorinated group;
quantum dots materials in the third quantum dots layer of the third color comprise a ligand having a fluorinated group; and
a number of fluorine atoms in the ligands of the third quantum dots layer of the third color is greater than a number of fluorine atoms in the ligands of the first quantum dots layer of the first color, and is greater than a number of fluorine atoms in the ligands of the second quantum dots layer of the second color.

17. The light emitting device of claim 1, comprising a first subpixel of the first color, a second subpixel of a second color, and a third subpixel of a third color;
wherein the first subpixel of the first color comprises the first quantum dots layer and the first auxiliary quantum dots layer;
the second subpixel of the second color comprises a second quantum dots layer and a second auxiliary quantum dots layer;
the third subpixel of the third color comprises a third quantum dots layer and a third auxiliary quantum dots layer;
quantum dots materials in the first auxiliary quantum dots layer comprise a ligand having a fluorinated group and/or a cyanide group;
quantum dots materials in the second auxiliary quantum dots layer comprise a ligand having a fluorinated group and/or a cyanide group;
quantum dots materials in the third auxiliary quantum dots layer comprise a ligand having a fluorinated group and/or a cyanide group; and
a thickness of the third auxiliary quantum dots layer is greater than a thickness of the first auxiliary quantum dots layer, and is greater than a thickness of the second auxiliary quantum dots layer.

18. The light emitting device of claim 1, comprising a first subpixel of the first color, a second subpixel of a second color, and a third subpixel of a third color;
wherein the first subpixel of the first color comprises the first quantum dots layer and the first auxiliary quantum dots layer;
the second subpixel of the second color comprises a second quantum dots layer and a second auxiliary quantum dots layer;
the third subpixel of the third color comprises a third quantum dots layer and a third auxiliary quantum dots layer;
quantum dots materials in the first auxiliary quantum dots layer comprise a ligand having a fluorinated group and/or a cyanide group;
quantum dots materials in the second auxiliary quantum dots layer comprise a ligand having a fluorinated group and/or a cyanide group;
quantum dots materials in the third auxiliary quantum dots layer comprise a ligand having a fluorinated group and/or a cyanide group; and
a number of the fluorinated group and/or a cyanide group in the third auxiliary quantum dots layer is greater than a number of the fluorinated group and/or a cyanide group in the first auxiliary quantum dots layer, and is greater than a number of the fluorinated group and/or a cyanide group in the second auxiliary quantum dots layer of.

19. The light emitting device of claim 1, comprising a first subpixel of the first color, a second subpixel of a second color, and a third subpixel of a third color;
wherein the first subpixel of the first color comprises the first quantum dots layer and the first auxiliary quantum dots layer;
the second subpixel of the second color comprises a second quantum dots layer and a second auxiliary quantum dots layer;
the third subpixel of the third color comprises a third quantum dots layer and a third auxiliary quantum dots layer; and
a thickness of the first auxiliary quantum dots layer is greater than a thickness of the second auxiliary quantum dots layer; and the thickness of the second auxiliary quantum dots layer is greater than a thickness of the third auxiliary quantum dots layer.

20. A display apparatus, comprising a display panel;
wherein the display panel comprises the light emitting device of claim 1, and one or more transistors configured to control light emission of the light emitting device.
